(19) United States
(12) Patent Application Publication
(10) Pub. No.: US 2026/0277119 A1
(43) Pub. Date: Sep. 17, 2026

(54) COMPUTER-IMPLEMENTED METHOD AND APPARATUS FOR PROCESSING A SAMPLE WITH A NANOMANIPULATOR

(71) Applicant: Carl Zeiss SMT GmbH, Oberkochen (DE)

(72) Inventors: Christof Baur, Darmstadt (DE); Markus Waiblinger, Griesheim (DE); Katharina Eberl, Frankfurt (DE); Rainer Fettig, Steinmauern (DE); Julia Weber, Alsbach-Haehnlein (DE); Dominik Schnoor, Dietzenbach (DE); Hans Hermann Pieper, Schaafheim (DE); Claudia Kroeckel, Egelsbach (DE)

(21) Appl. No.: 19/657,870

(22) Filed: Apr. 24, 2026

Related U.S. Application Data
(63) Continuation of application No. PCT/EP2024/080392, filed on Oct. 28, 2024.

(30) Foreign Application Priority Data
Oct. 27, 2023 (DE) 102023129684.1

(51) Int. Cl. G03F 7/00

(52) U.S. Cl. CPC G03F 7/706837; G03F 7/7065; G03F 7/70655; G03F 7/706851; G03F 7/70975

(57) ABSTRACT

A computer-implemented method for processing a sample arranged on a sample stage with a nanomanipulator comprising a tip for processing the sample and a positioning unit for moving the tip, the method comprising the following steps:
focusing (S10) an image provided by an image recording device on the tip and/or the sample;
selecting (S11) the sample or the tip as a target feature; and
automatically setting (S12) a focal point of the nanomanipulator based on at least one operating parameter of one of the sample stage and the positioning unit indicative of a vertical movement of the sample stage and/or the positioning unit, respectively, so as to keep the target feature focused within the image provided by the image recording device during processing.

### CROSS-REFERENCE TO RELATED APPLICATIONS

This application is a continuation of and claims benefit under 35 U.S.C. § 120 from PCT Application No. PCT/EP2024/080392, filed on Oct. 28, 2024, which claims priority from German Application No. 10 2023 129 684.1, filed on Oct. 27, 2023. The entire contents of each of these earlier applications are incorporated herein by reference.

### TECHNICAL FIELD

The present invention relates to a computer-implemented method and an apparatus for processing a sample with a nanomanipulator.

### BACKGROUND

Microlithography is used for producing microstructured components, such as for example integrated circuits. The microlithography process is carried out using a lithography apparatus comprising an illumination system and a projection system. The image of a mask (reticle) illuminated by use of the illumination system is projected here by use of the projection system onto a substrate, for example, a silicon wafer, which is coated with a light-sensitive layer (photoresist) and arranged in the image plane of the projection system, in order to transfer the mask structure to the light-sensitive coating of the substrate.

The mask (i.e., lithography mask) is used here for a multiplicity of exposures, for which reason it is very important that the mask is free of defects and contaminations. Therefore, lithography masks are examined in regard to defects and contaminations at great expense. Attempts are then made to repair identified defects or to remove contaminations. The defects and contaminations may be extremely small and have sizes in the range of a few nanometers. Therefore, removing them requires apparatuses with very high spatial resolution.

The contaminations are, for example, extremely small particles which have deposited on the mask from the surroundings. Such contaminations occur to an increased extent, for example, if the mask is transferred between different processing apparatuses. The particles are of a very diverse nature and have different sizes and/or shapes. They may, for example, be metal particles, in particular tin, but ceramic particles, polymer particles and further carbon compounds may also occur. The particles are typically adsorbed on the mask surface, that is to say that there are no strong chemical bonds, such as atomic bonds, between the particle material and the mask surface.

A particle will leave the mask surface if applied attractive forces (e.g., Coulomb forces and van der Waals forces) for removing the particle are greater than attractive forces (e.g., Coulomb forces and van der Waals forces) of the mask surface. Depending on what kind of interaction there is between the particle and the mask surface, an activation energy may be necessary to break the existing bond to the mask surface.

Processing apparatuses are known which can remove individual particles from a surface in a targeted manner (referred to as: particle removal tool, PRT). By way of example, nanomanipulators, such as for example atomic force microscopes, are used for this purpose. In this case, a particle is picked up by a measuring tip (measuring and manipulator tip) of the nanomanipulator and, adhering to the measuring tip, is removed from the mask surface. Particle removal is usually supported by imaging methods (e.g., image recording by use of a scanning electron microscope and/or a scanning ion microscope) and requires manipulations by a user on nanometer scales. In this case, small errors on the part of a user may easily result in damage or destruction of the measuring tip of the nanomanipulator or of the sample. Moreover, the processing requires high attentiveness on the part of the user, as a result of which fatigue phenomena lead to an increased risk of errors on the part of the user.

### SUMMARY

Against this background, an aspect of the present invention is to improve the processing of a sample with a nanomanipulator.

Accordingly, a method, in particular a computer-implemented method, for processing a sample with a nanomanipulator is proposed. The nanomanipulator comprises a tip for processing the sample and a positioning unit for moving the tip. The method comprising the following steps:
focusing an image provided by an image recording device on the tip and/or the sample;
selecting the sample or the tip as a target feature; and
automatically setting a focal point of the nanomanipulator based on at least one operating parameter of one of the sample stage and the positioning unit indicative of a vertical movement of the sample stage and/or the positioning unit, respectively, so as to keep the target feature focused within the image provided by the image recording device during processing.

Optionally, the image provided by the image recording device is focused on the tip and the sample while the tip is in contact with the sample.

Optionally, the target feature is selected by an operator of the nanomanipulator through a human-machine interface.

Optionally, in case the sample is selected as target feature, the focal point is automatically set based on a z-value indicative of a vertical position of the sample stage and, in case the tip is selected as target feature, the focal point is automatically set based on a z-value indicative of a vertical position of the positing unit.

Optionally, the method further comprises switching the target feature from the sample to the tip or vice versa, while the tip is not in contact with the sample.

Optionally, the method further comprises, after switching the target feature, setting a focal point of the nanomanipulator based on the at least one operating parameter of the respective other one of the sample stage and the positioning unit.

Optionally, the target feature is switched by an operator of the nanomanipulator through a human-machine interface.

Optionally, the target feature is switched repeatedly between the sample and the tip, the method further comprising displaying a first image and a second image in a concurrent or alternating and/or stroboscopic manner. The first image is provided by the image recording device when the focal point is set based on the at least one operating parameter of one of the sample stage, such that the sample is in focus within the first image. The second image is provided by the image recording device when the focal point is set based on the at least one operating parameter of one of the positioning unit, such that the tip is in focus within the second image.

The above methods may be used for tracking a particle to be removed from the sample. The use comprises: focusing the image provided by the image recording device when the tip of the nanomanipulator is in contact with a particle located on a surface of the sample; selecting the tip as a target feature; and separating the tip from the sample by operating the sample stage and/or the positioning unit in a vertical direction, while keeping the tip focused within the image provided by the image recording device during processing, so as to visually verify whether the particle is lifted by the tip from the surface of the sample.

Optionally, the use further comprises: focusing the image provided by the image recording device on the tip to determine an initial horizontal position of the tip before the tip is in contact with the sample; focusing the image provided by the image recording device on the sample to provide an initial horizontal position of the sample before the tip is in contact with the sample; and bringing the tip in contact with the particle by operating the sample stage and/or the positioning unit in a vertical direction and/or aligning the horizontal positions of the tip and the sample by operating the sample stage and/or the positioning unit in a horizontal direction.

The above methods may also be used for following a replacement tip during a tip change procedure, comprising: focusing the image provided by the image recording device on a tip changing mask, carrying one or more replacement tips; selecting the tip changing mask as a target feature; and vertically aligning a target tip located on the tip changing mask in a central area of the image, while the focal point of the nanomanipulator is set on the tip changing mask.

Optionally, the use further comprises: attaching the target tip to the positioning unit; selecting the target tip as feature of interest; and lifting the target tip attached to the positioning unit from the tip changing mask, while the focal point of the nanomanipulator is set on the target tip.

According to another aspect, a computer-implemented method for processing a sample with a nanomanipulator is proposed. The nanomanipulator comprises a measuring tip for processing the sample and a positioning unit for moving the measuring tip. The method comprises the following steps:
a) providing permitted value ranges for two or more parameters of the nanomanipulator and/or of the sample, wherein the two or more parameters span a multidimensional parameter space,
b) ascertaining a permitted region in the multidimensional parameter space based on the provided permitted value ranges for the two or more parameters,
c) receiving current values and/or ascertaining future values of the two or more parameters,
d) ascertaining whether a state point corresponding to the current and/or future values of the two or more parameters in the multidimensional parameter space lies outside the permitted region, and
e) controlling the positioning unit in order to stop a movement of the measuring tip and/or in order to withdraw the measuring tip in relation to the sample if it is ascertained that the state point lies outside the permitted region.

The method enables a plurality of parameters of the nanomanipulator and/or of the sample (e.g., process parameters of the nanomanipulator and/or properties of the sample) to be monitored automatically and simultaneously. In particular, the parameters are monitored fully automatically, i.e., without action by a user. By way of example, the parameters are monitored with the aid of a control apparatus.

The method involves ascertaining a permitted region in the multidimensional parameter space spanned by the plurality of monitored parameters. The permitted region is ascertained, e.g., by the control apparatus. The permitted region is defined in such a way that damage to the sample and/or impairment of the function of the nanomanipulator and/or damage to the nanomanipulator (e.g., the measuring tip, the cantilever or other components of the nanomanipulator) are/is prevented for state points in the permitted region. The method involves checking, e.g., by use of the control apparatus, whether a current and/or future state point adopted by the system comprising nanomanipulator and sample, in relation to the monitored parameters, is situated within or outside the permitted region. If a current and/or future state point is present outside the permitted region, then safety measures for protecting the sample and/or the nanomanipulator are automatically initiated, e.g., by the control apparatus. In particular, a movement of the measuring tip (e.g., a lateral movement and/or a movement in a plane parallel to a main extension plane of the sample, and/or an approaching movement by the measuring tip in relation to the sample) is stopped and/or the measuring tip is withdrawn in relation to the sample (e.g., removed from the sample).

Stopping a movement (e.g., lateral movement and/or approaching movement in the direction of the sample) of the measuring tip makes it possible to prevent penetration into a forbidden region in the multidimensional parameter space. By way of example, the multidimensional parameter space can comprise a force on the measuring tip perpendicular to the sample surface and a force on the measuring tip parallel to the sample surface. Stopping a movement of the measuring tip then makes it possible to prevent, for example, penetration into a forbidden region in which an inadmissibly high force is applied to the measuring tip perpendicular to the sample surface and/or parallel to the sample surface. By way of example, the multidimensional parameter space can also comprise, in addition or instead, a position (e.g., lateral position and/or a distance from the sample) of the measuring tip relative to the sample. Stopping a movement (e.g., lateral movement and/or approaching movement to the sample) of the measuring tip then makes it possible to prevent, for example, a harmful interaction (e.g., a collision) with structures of the sample.

Withdrawing the measuring tip in relation to the sample, i.e., moving the measuring tip perpendicular to the sample and in a direction facing away from the sample, makes it possible to end contact between the measuring tip and the sample and/or to increase a distance between the measuring tip and the sample.

The ascertained permitted region in the multidimensional parameter space is a region in which safe processing of the sample with the nanomanipulator and safe operation of the nanomanipulator are possible.

The sample is, for example, a lithography mask having structures (e.g., absorber structures). The structures have, for example, a structure size in the range of 10 nm-10 μm. The structures are arranged, for example, in a structure pattern for producing a specific type of semiconductor chip. The sample can be, for example, a transmissive lithography mask for DUV lithography (DUV: “deep ultraviolet”, operating light wavelengths in the range of 30-250 nm) or a reflective lithography mask for EUV lithography (EUV: “extreme ultraviolet”, operating light wavelengths in the range of 1-30 nm, in particular 13.5 nm).

The sample can also be a microelectronic component, such as for example an integrated circuit, in particular a CPU (CPU: “central processing unit”), GPU (GPU: “graphics processing unit”), a RAM memory (RAM: “random access memory”), a flash memory and suchlike.

The nanomanipulator, e.g., the atomic force microscope, and/or a superordinate apparatus comprising the nanomanipulator comprise(s), for example, a sample stage device having a mount, a sample stage for arranging the sample, said sample stage being arranged movably on the mount, and a further positioning unit for moving the sample stage relative to the mount. The sample stage can be moved, for example, with the aid of the further positioning unit in the x-direction and the y-direction (i.e., laterally) and/or in the z-direction (vertical direction). The sample stage can, for example, also be mounted rotatably on the mount, such that it can be rotated about the x-, y- and/or z-direction with the aid of the further positioning unit. The sample stage comprises in particular a surface for arranging the sample.

The nanomanipulator, e.g., the atomic force microscope, comprises a cantilever, for example, on which the measuring tip is arranged and/or secured. The cantilever and the measuring tip can also be embodied in monolithic fashion. The term cantilever also appears in the German text as “Cantilever”. The measuring tip has, for example, a length in the range of 0.5 μm-1 mm and a diameter in the range of 20 nm-1 μm. In particular, the measuring tip can taper towards its free end. The measuring tip comprises, for example, a material comprising carbon, silicon, one or more noble metals, tungsten, platinum, iridium and/or a platinum-iridium alloy. The measuring tip makes it possible to move to individual positions on the sample surface in a targeted manner, in particular even if the sample has structures having a high aspect ratio. The aspect ratio may be defined, for example, as the ratio of width to height of a structure. An example of a structure having a high aspect ratio of 1:10 is a narrow, deep trench which, for example, is 1 μm wide and 10 μm deep.

The measuring tip is in particular a tip configured for measuring and for manipulating (measuring and manipulator tip).

The nanomanipulator comprises a positioning unit, on which the cantilever is mounted movably and which enables the cantilever to be moved in three spatial directions relative to the positioning unit (translational movement in the three spatial directions). The three spatial directions span in particular a three-dimensional space. The positioning unit is secured, for example, to a housing of the nanomanipulator and/or a superordinate apparatus comprising the nanomanipulator.

The cantilever has in particular an elongate shape having a longitudinal axis. Furthermore, the cantilever is secured to the positioning unit movably at a first end in relation to its longitudinal axis. With the aid of the positioning unit, a position of the first end of the cantilever (also called base point or base end of the cantilever) can thus be set in the three spatial directions. Moreover, the cantilever has the measuring tip at a second end in relation to its longitudinal axis.

If the measuring tip comes into the vicinity of the sample surface, an interaction occurs between the measuring tip and the sample surface. The interaction may be based on direct contact, on a van der Waals interaction or further physical interactions, and mixtures thereof. By way of the measuring tip being moved (scanned) over the sample surface, a three-dimensional image of the sample surface can be captured. In this case, for example, for each scanning position the distance between the measuring tip and the sample surface is kept constant by use of a closed-loop control circuit and a position of a microactuator for setting the distance is captured.

In particular, the particle is a foreign body, such as dust or dirt, which has deposited on the sample surface. It may also be said that the particle is adsorbed on the sample surface. Particles adsorbed on the sample surface may have different constitutions and different shapes. The size of the particles may, for example, assume values in the range of 3 nm-50 μm and/or 10 nm-1 μm.

Such a particle can, for example, be located on the sample surface by use of optical analysis methods and approached by the measuring tip in a targeted manner. In order to pick up the particle with the measuring tip, the particle must be detached from the sample surface. That means that the forces acting between the sample surface and the particle must be overcome. The strength with which the particle is bonded to the sample surface depends both on the shape and constitution of the particle and on the constitution of the sample surface, in particular the surface energy thereof. The greater the surface energy of the surface, the more strongly the particle is adsorbed.

To pick up the particle with the measuring tip, the measuring tip is, for example, brought into contact with the particle. If attractive forces of the measuring tip are greater than attractive forces of the sample surface, the particle will be able to be detached from the sample surface and can be picked up by the measuring tip.

It may be helpful to first use the measuring tip to displace the particle on the sample surface in order to break existing bonds between particle and sample surface. It is thereby possible, for example, to reduce the bonding energy of the particle in relation to bonding to the surface. Furthermore, for example, a contact area between the measuring tip and the particle can be increased as a result. If the contact area between the particle and the measuring tip becomes larger, the probability that the particle will adhere to the measuring tip and be able to be detached from the sample surface increases.

After the particle has been picked up by the measuring tip, the particle must be removed again from the measuring tip in order to be able to continue to use the measuring tip. The particle should in this case in particular be deposited at a position on the sample surface at which it is not a disturbance, or on a separate deposition unit.

The nanomanipulator can be part of a superordinate apparatus for processing the sample, the apparatus comprising the nanomanipulator. The superordinate apparatus for processing the sample can, for example, also comprise a control apparatus for carrying out the proposed method. Moreover, the superordinate apparatus for processing the sample can, for example, also comprise an image recording device for recording images of the sample, such as e.g. a scanning electron microscope and/or a scanning ion microscope.

In order to safely process the sample with the nanomanipulator, parameters of the nanomanipulator and/or of the sample, such as for example process parameters of the nanomanipulator and properties of the sample, are monitored. For this purpose, a control apparatus (e.g., of the nanomanipulator and/or of the superordinate apparatus) receives, for example, current values of two or more of these parameters. The control apparatus can, for example, also be configured to ascertain (i.e., predict) future values of two or more of these parameters based on stored information and/or received information.

Receiving the current values and/or ascertaining the future values of the two or more parameters take(s) place in particular during the processing of the sample with the measuring tip.

Furthermore, the method involves providing permitted value ranges for the two or more parameters. These permitted value ranges are, for example, predetermined permitted value ranges which are stored in a storage device of the control apparatus and/or are received by the control apparatus. The permitted value ranges for the two or more parameters are in each case one-dimensional value ranges, in particular. If, for example, one of the monitored parameters is a force on the measuring tip perpendicular to the sample surface, then a permitted value range is, for example, the range from a force zero to a maximum permissible absolute value of the force F max perpendicular to the sample surface, and/or to a maximum permissible positive or negative force perpendicular to the sample surface.

By way of example, the permitted region can also be calculated based on the permitted value ranges for the two or more parameters and on a calculation of a probability of the sample being damaged (damage probability). In this case, this damage probability is highly non-linearly dependent on the parameters.

The two or more monitored parameters span a multidimensional parameter space in such a way that a number n of parameters span an n-dimensional parameter space, where n is a natural number greater than or equal to two.

The permitted region is in particular a multidimensional permitted region. The permitted region has, for example, the same dimension as the multidimensional parameter space spanned by the monitored parameters.

If, for example, four parameters are monitored (n=4), a four-dimensional parameter space is thus taken into consideration. Moreover, the permitted region is in this case, for example, a permitted four-dimensional region in the four-dimensional parameter space.

The permitted region is ascertained, for example, based on the provided permitted value ranges for the two or more monitored parameters, such that for each monitored parameter its associated (one-dimensional) permitted value range is taken into account.

A current and/or future state point of the system comprising nanomanipulator and sample in the multidimensional parameter space is accordingly ascertained based on the received current and/or ascertained future values of the two or more parameters. Given a number n of monitored parameters which span an n-dimensional monitored parameter space, a current and/or future state point is a point in the n-dimensional space which is given (e.g., uniquely defined) by a number n of coordinates.

By ascertaining whether the current and/or future state point is situated within the permitted region of the n-dimensional parameter space, and by automatically initiating countermeasures if it is ascertained that the current and/or future state point is situated outside the permitted region, it is possible to simplify processing of the sample with the nanomanipulator for a user.

In embodiments, step e) can also be carried out depending on a residence duration outside the permitted region (e.g., in a warning region and/or a forbidden region).

By way of example, a movement of the measuring tip can be stopped and/or the measuring tip can be withdrawn in relation to the sample perpendicular to the sample only if it is ascertained that the state point is adopted outside the permitted region for a predetermined residence duration. The permissible residence duration may be of different lengths for different regions outside the permitted region (e.g., warning region, forbidden region). In particular, a predetermined first residence duration for residing in the warning region may be longer (e.g., 1 second) than a predetermined second residence duration for residing in the forbidden region (e.g., 0.01 second).

In accordance with one embodiment, the future values of the two or more parameters are predicted based on a received user input and/or based on an ascertained drift movement of the measuring tip relative to the sample.

The future values of the monitored two or more parameters can thus be ascertained, i.e., predicted, for example, based on a received user input. A user input is effected, for example, with the aid of a human-machine interface (HMI), such as for example a keyboard, a mouse pointer, joystick, game controller, touchscreen or the like. By way of ascertaining the future values of the monitored two or more parameters based on a received user input, a target position of the measuring tip input by a user by use of the human-machine interface can be checked with respect to the monitored parameters. If executing the user input would result in the ascertained permitted region in the multidimensional parameter space being left, then for example a movement of the measuring tip can be stopped and the user input thus cannot be executed or can be only partly executed. Alternatively, the measuring tip can also be withdrawn in relation to the sample, such that a distance between the measuring tip and the sample surface is large enough that execution of the user input is harmless.

The future values of the monitored two or more parameters can, for example, also be ascertained, i.e., predicted, based on an ascertained drift movement of the measuring tip relative to the sample. As a result, drift monitoring (referred to as: drift guard) is possible, e.g., even without a user input being present. It is known that such a drift movement of the measuring tip relative to the sample may occur as a result of thermal drift (e.g., heating up of the measuring tip and/or of the cantilever) or charging of the sample surface on account of processing with a particle beam (e.g., imaging by a scanning electron microscope), as a result of which a force between measuring tip and sample is increased, which leads to the drift. So-called “subsequent creeping” of the measuring tip when moving to a specific position on the sample is also known.

A drift movement of the measuring tip relative to the sample can be ascertained, for example, by use of image processing of repeated image recordings of the sample which capture both the measuring tip and a structure and/or marking (e.g., drift marker) of the sample. If a further drift movement would result in the permitted region in the multidimensional monitored parameter space being left, then a movement of the measuring tip can be stopped and/or the measuring tip can be withdrawn from the sample.

In accordance with a further embodiment, the method comprises:
ascertaining a warning region in the multidimensional parameter space for the two or more parameters,
ascertaining whether the current and/or future state point in the multidimensional parameter space lies within the ascertained warning region, and
controlling the positioning unit so that a movement of the measuring tip is slowed down and/or controlling a human-machine interface in order to output a warning if it is ascertained that the current and/or future state point lies within the ascertained warning region.

By ascertaining the warning region, it is possible to provide a buffer zone between permitted region and forbidden region in the parameter space of the monitored parameters. As a result, before the forbidden region is reached, it is possible to output a warning for a user or to change control parameters of the nanomanipulator, e.g., to slow down a speed at which the measuring tip is moved.

By way of example, the method involves providing (e.g., reading from a storage unit and/or receiving) (e.g., predetermined) warning value ranges for the two or more parameters and ascertaining the multidimensional warning region based on the provided warning value ranges.

Alternatively, the multidimensional warning region can also be ascertained (e.g., calculated) based on the ascertained permitted region. By way of example, for all the monitored parameters a core range (e.g., 90%) of the permitted value ranges respectively provided can be used for ascertaining the permitted multidimensional region. Furthermore, by way of example, for all the monitored parameters a marginal range (e.g., the remaining 10%) of the permitted value ranges provided can be used for ascertaining the multidimensional warning region.

By way of example, the warning region and/or a forbidden region can also be ascertained based on a calculation of probabilities of damage to the sample and/or the nanomanipulator occurring for specific parameter values. The probability of this damage may be greatly non-linearly dependent on the parameter values.

The warning region is in particular a multidimensional warning region. A dimension of the warning region is, for example, of exactly the same magnitude as a dimension of the permitted region and a dimension of the monitored parameter space.

The warning region is, for example, a region adjacent to the permitted region. The warning region is arranged, for example, between the permitted region and a forbidden region. For example, the warning region surrounds (e.g., completely) the permitted region in the multidimensional parameter space.

In embodiments, the positioning unit of the nanomanipulator can also be controlled in such a way that a state point of the monitored parameters is moved back from the warning region into the permitted region if it is ascertained that the current and/or future state point lies within the ascertained warning region.

In accordance with a further embodiment, the permitted region, the warning region and/or a forbidden region of the multidimensional parameter space have discrete limits or the permitted region, the warning region and/or the forbidden region continuously merge into one another.

In a case in which the permitted region, the warning region and/or the forbidden region continuously merge into one another, it is thus possible to define a steplessly variable safety map (damage probability map) in the multidimensional parameter space. By way of example, the permitted region, the warning region and/or the forbidden region can be ascertained based on a calculation of a probability of the sample and/or the measuring tip incurring damage. By way of example, it is possible to calculate a damage probability for each state point in the multidimensional parameter space or a safety level in regard to the measuring tip and/or the sample not being damaged for each state point in the multidimensional parameter space and thus to ascertain the damage probability map or safety map. The damage probability of a state point may be in particular greatly non-linearly dependent on the values of the monitored parameters.

In a case in which the permitted region, the warning region and/or the forbidden region continuously merge into one another, step e) can optionally be carried out depending on a penetration depth into the warning region. By way of example, a speed at which the measuring tip is withdrawn from the sample in step e) can be all the greater, the further a current state point has advanced from the permitted region into the warning region.

The forbidden region is in particular a multidimensional forbidden region.

In accordance with a further embodiment, the nanomanipulator comprises a cantilever, which at its base end is movably secured to the positioning unit. Furthermore, the measuring tip is arranged at a free end of the cantilever. Moreover, the two or more parameters of the nanomanipulator and/or of the sample comprise:
a position of the base end of the cantilever relative to the positioning unit,
a speed of the base end of the cantilever relative to the positioning unit,
a deflection of the free end of the cantilever in a z-direction arranged perpendicular to the sample,
a rotation of the free end of the cantilever about an x-direction arranged perpendicular to the z-direction,
a bending of the measuring tip relative to the cantilever, and/or
position data of structures of the sample.

As a result, a multidimensional, complex parameter space can be efficiently monitored in relation to process parameters of the nanomanipulator, e.g., of the atomic force microscope, and/or of the sample.

In particular, the position of the base end of the cantilever relative to the positioning unit (e.g., in three spatial directions spanning a three-dimensional space), the speed of the base end of the cantilever relative to the positioning unit (e.g., in the three spatial directions), the deflection (e.g., an extent of the deflection) of the cantilever at its free end in the z-direction, the rotation (e.g., an extent of the rotation) of the cantilever at its free end about the x-direction and/or the bending (e.g., an extent of the bending) of the measuring tip relative to the cantilever are captured (e.g., measured).

The position of the base end of the cantilever relative to the positioning unit and the speed of the base end of the cantilever relative to the positioning unit can be set in particular by control of the positioning unit. Furthermore, current values of the position and speed of the base end of the cantilever relative to the positioning unit are provided by the positioning unit, for example.

The deflection of the free end of the cantilever in the z-direction is caused by forces that act between the measuring tip and the sample. The deflection of the free end of the cantilever in the z-direction is moreover proportional to a spring constant of the cantilever. In particular, the cantilever bends to different extents during the scanning of the sample according to the forces acting between measuring tip and sample. An extent of this bending or deflection of the free end of the cantilever in the z-direction can be captured with the aid of a light pointer device, for example. The nanomanipulator, e.g., the atomic force microscope, and/or a superordinate apparatus comprising the nanomanipulator comprise(s) such a light pointer device, for example.

The parameters of the nanomanipulator can, for example, also comprise a deflection of the free end of the cantilever in a direction which deviates from the z-direction (the direction perpendicular to the sample) by an angle of 30° or less, 20° or less, 10° or less, 5° or less, 3° or less, and/or 1° or less.

The light pointer device comprises, for example, a laser source and a position-sensitive photodetector. A laser beam emitted by the laser source is directed at the free end of the cantilever and reflected from there in an undeflected position of the cantilever into the center of the position-sensitive photodetector. The photodetector is subdivided, for example, into four regions “top left”, “top right”, “bottom left” and “bottom right”. If the bending (deflection) of the cantilever changes, then the reflected laser spot shifts on the photodetector as in the case of a light pointer. By measuring the intensities in the four regions of the photodetector, it is possible to determine vertical and horizontal bending signals which are proportional to the normal force and respectively to lateral forces.

The z-direction is arranged, for example, perpendicular to a main extension plane of the sample.

Forces acting between the measuring tip and the sample can also cause a rotation (torsion) of the free end of the cantilever about the x-direction. This can also be captured with the aid of the light pointer device described.

Moreover, bending (i.e., an elastic deformation) of the measuring tip relative to the cantilever can occur as a result of interaction of the measuring tip with the sample (e.g., as a result of a lateral movement of the measuring tip upon contact between the measuring tip and the sample).

An extent of this bending of the measuring tip relative to the cantilever can be ascertained by use of image processing in recorded images (e.g., scanning electron microscope images, scanning ion microscope images) of the measuring tip.

In embodiments, the positioning unit can also comprise a stationary positioning component (which is secured, e.g., to a housing of the nanomanipulator) and a positioning component which is movable relative to the stationary positioning component and on which the base end of the cantilever is fixedly mounted. A position of the base end of the cantilever can then be moved together with the movable positioning component of the positioning unit. Furthermore, the position of the base end of the cantilever together with the movable positioning component can be moved relative to the stationary positioning component. In this case, the two or more parameters of the nanomanipulator comprise, for example, a position of the base end of the cantilever relative to the stationary positioning component of the positioning unit and/or a speed of the base end of the cantilever relative to the stationary positioning component of the positioning unit.

The two or more parameters of the nanomanipulator can additionally or instead also comprise a spring constant of the cantilever, an opening angle of the measuring tip and/or a length of the measuring tip.

In accordance with a further embodiment, the method furthermore comprises:
receiving images of at least one part of the sample which have been recorded by a scanning electron microscope,
wherein the two or more parameters of the nanomanipulator and/or of the sample comprise a quantity of charge at a surface of the sample.

As a result, an accumulation of charge caused by a high-energy electron beam on the sample surface can be concomitantly monitored in the multidimensional parameter space.

In particular, the removal of particles from the sample with the nanomanipulator is usually monitored with the aid of a scanning electron microscope, which causes the aforementioned high electron beam dose on the sample surface.

In embodiments, the scanning electron microscope is controlled to stop a recording of images of the at least one part of the sample if it is ascertained that a current and/or future value of the quantity of charge on the surface of the sample lies outside a permitted value range for the quantity of charge on the surface of the sample.

In embodiments, a human-machine interface is controlled to output a request for a user to carry out a discharging process (e.g., by use of a plasma source) of the sample surface if it is ascertained that a current and/or future value of the quantity of charge on the surface of the sample lies outside a permitted value range for the quantity of charge on the surface of the sample.

In accordance with a further embodiment, providing the permitted value ranges for the two or more parameters comprises providing and/or ascertaining position data of structures of the sample.

The structures of the sample are, for example, absorber structures of a lithography mask.

A main extension plane of the sample is, for example, an xy-plane. The position data of structures of the sample define, for example, forbidden value ranges in relation to an x-position and in relation to a y-position in the xy-plane. By way of example, the xy-positions on the sample surface in which the structures are present are forbidden regions. By way of example, the xy-positions on the sample surface in which edges of the structures are present are forbidden regions. The xy-positions of the sample surface in which the structures are not present are thus permitted regions or permitted and (close to a respective structure edge) warning regions.

In accordance with a further embodiment, ascertaining the position data of the structures of the sample comprises:
receiving one or more images of at least one part of the sample, and ascertaining the position data of the structures of the sample by use of image analysis of the one or more received images and/or by use of edge recognition of edges of the structures in the one or more received images.

In particular, the one or more images of the sample are received from an image recording device, e.g., a scanning electron microscope and/or a scanning ion microscope.

In accordance with a further embodiment, ascertaining the position data of the structures of the sample comprises:
receiving an image of at least one part of the sample, wherein the image captures a defect-free region with a first portion of the structures and a defective region with at least one defect and a second portion of the structures, and wherein a geometric shape of the first portion of the structures corresponds to (e.g., matches) a geometric shape of the second portion of the structures,
ascertaining the geometric shape of the first portion of the structures in the defect-free region by use of image analysis, and
ascertaining the position data of the second portion of the structures in the defective region based on the ascertained geometric shape of the first portion of the structures in the defect-free region.

As a result, recognizing the structures and ascertaining their position data can advantageously take place in a defect-free region of the sample. The position data of the structures can thus be ascertained more accurately.

A defect is, for example, a particle (e.g., a foreign body).

In accordance with a further embodiment, the method comprises:
receiving an image of at least one part of the sample,
controlling a display device in order to represent the image,
receiving a target position of the measuring tip in the image, said target position being input by a user by use of a graphical user interface, and
fully automatically controlling the positioning unit in order to move the measuring tip to the target position.

As a result, a user merely needs to select (e.g., click on) a target location in the recorded image by use of the graphical user interface (e.g., a mouse pointer) and the measuring tip is then fully automatically moved to this target location.

In this case, for example, image processing functions, such as for example pattern recognition, can be employed in order to ascertain the measuring tip and its location in the recorded image. Alternatively, a method as described in U.S. Pat. No. 7,675,300 B2 can also be employed in order to identify the measuring tip and to determine its position.

By way of example, it is also possible for a plurality of images of at least one part of the sample to be recorded and received. The images can be recorded, e.g., at a high rate (video mode) and the image processing can be carried out in real time.

In accordance with a further embodiment, the method comprises:
ascertaining whether a time duration since receiving a last user input is greater than a threshold value, and
fully automatically controlling the positioning unit in order to move the measuring tip into the ascertained permitted region of the multidimensional parameter space if the time duration since receiving the last user input is greater than the threshold value.

A deadman switch is provided as a result. In particular, it is possible to prevent the system from going into the warning region and/or forbidden region.

The permitted region (safe region) is attained, for example, by (i) the z-feedback being activated and the force between measuring tip and sample thus being kept constant at low force; (ii) the measuring tip being withdrawn from the sample with the aid of a fine adjustment (e.g., by a few micrometers); (iii) the measuring tip being withdrawn from the sample with the aid of a coarse adjustment (e.g., by 100 micrometers); and/or (iv) the sample stage being moved away from the measuring tip (e.g., by a few millimeters).

In accordance with a further embodiment, the method comprises:
receiving a plurality of images of at least one part of the sample, wherein the images capture a structure and/or marking of the sample and the measuring tip, and
ascertaining a drift movement of the measuring tip relative to the structure and/or the marking of the sample by image analysis of the received images, and/or
ascertaining a drift correction based on the ascertained drift movement and/or based on predetermined model data, and
fully automatically controlling the positioning unit in order to move the measuring tip according to the ascertained drift correction.

As a result, a drift movement on account of thermal drift and/or charging of the sample surface can be fully automatically corrected without control by a user.

The marking is, for example, a drift marking of the sample.

The model data in the case of a thermal drift comprise, for example, a linear model with a constant drift rate.

In accordance with a further embodiment, the method comprises:
controlling an image recording device in order to record a first image of a defective portion of the sample, which first image captures first structures of the sample and one or more defects of the sample,
controlling the image recording device in order to record a second image of a defect-free portion of the sample, which second image captures second structures of the sample, the geometric shape of which corresponds to a geometric shape of the first structures in the first image,
ascertaining a difference image based on a subtraction of the second image from the first image,
ascertaining position data of the one or more defects captured in the first image based on an image analysis of the difference image, and
controlling the image recording device in order to record a third image of a defective portion of the sample, in which the one or more defects captured in the first image is/are arranged at a predetermined position in the image (e.g., in an image center).

The sample is, for example, a microlithographic lithography mask. The sample comprises, for example, a structure pattern for producing a specific type of semiconductor chip (die). This structure pattern is repeated a number of times on the lithography mask, for example, in order to produce a plurality of semiconductor chips (dice) of identical type using one and the same lithography mask. By way of example, the first structures in the first image serve for producing a first semiconductor chip and the second structures in the second image serve for producing a second semiconductor chip of the same type. Since the first and second structures correspond to one another, they are eliminated when the difference image is ascertained (“D2D”, which stands for “die to die”), such that the difference image does not contain any structures and the defect is imaged with greater contrast. Consequently, a position of the defect can be ascertained more accurately based on the difference image. Moreover, by use of the very accurately ascertained position of the defect, a third image centered on the defect (e.g., a particle) can be recorded fully automatically. This facilitates the further processing by a user.

The image recording device is a scanning electron microscope, for example.

By way of example, before the image recording device is controlled in order to record the first and second images, “coarse” position data of one or more defects (e.g., particles) of the sample are provided. Furthermore, proceeding from these “coarse” position data, by use of the method steps proposed in accordance with this embodiment, more accurate position data of one or more defects (e.g., particles) of the sample are ascertained, which in particular are more accurate than the “coarse” initial position data.

Ascertaining the difference image based on the subtraction of the second image from the first image comprises, for example, a mathematical subtraction of the second image from the first image. By way of example, the first and second images each comprise a two-dimensional arrangement of pixels and an intensity value assigned to each pixel. By way of example, the first and second images comprise an identical number of pixels and an identical arrangement of the pixels. In the course of mathematically subtracting the second image from the first image, for example, for each pixel of the first image, an intensity value of the corresponding pixel of the second image is subtracted (taken away) from an intensity value assigned to said pixel of the first image. The difference between the two intensity values yields an intensity value of a corresponding pixel of the difference image. The difference image comprises in particular an identical number of pixels and an identical arrangement of the pixels vis-à-vis the first and second images.

Furthermore, ascertaining the difference image based on the subtraction of the second image from the first image can, for example, also comprise producing an image excerpt from the first and/or second image, an image registration of the first and second images, and/or applying an image filter to the first and/or second image.

In embodiments, the method comprises:
controlling an image recording device in order to record one or more first images of at least one part of the sample, in which a reference structure and one or more defects of the sample are captured,
ascertaining position data of the one or more defects captured in the one or more first images relative to the reference structure based on an image analysis, and
controlling the image recording device in order to record one or more second images of at least one part of the sample, in which the one or more defects captured in the first image is/are arranged at a predetermined position in the image (e.g., in an image center) relative to the reference structure.

As a result, a defect (e.g., a particle), in the course of repeated recording of images, can be automatically kept at a predetermined position in the image (e.g., in an image center) (referred to as: particle tracking).

In accordance with a further embodiment, the nanomanipulator comprises a cantilever, which at its first end is mounted at a fixed angle on the positioning unit and at the second end of which the measuring tip is arranged. Moreover, the sample is arranged on a rotatable sample stage. In addition, the method comprises:
receiving an image of at least one part of the sample, wherein the image captures structures of the sample and a defect,
ascertaining an access angle for the measuring tip in order to process the defect in such a way that an access path with the access angle is free of structures of the sample, and
controlling the sample stage in order to rotate the sample stage based on the ascertained access angle in such a way that the fixed angle of the measuring tip corresponds to the access angle.

As a result, it is possible to set an angle between measuring tip and sample which is advantageous for processing the defect.

In particular, here an access angle for the measuring tip in order to process the defect is ascertained in such a way that a linear access path having the access angle is free of structures of the sample.

The access path is, for example, also a removal trajectory and/or part of a removal trajectory for removing a particle (as an example of a defect). The access path is arranged in the xy-plane, for example, which is arranged, e.g., parallel to the main extension plane of the sample. The access path is a linear access path, for example. The access angle also lies in the xy-plane, for example. The access angle is in particular an angle between a first straight line parallel to the longitudinal direction of the cantilever and a second straight line parallel to the access path. The fixed angle at which the cantilever is secured to the positioning unit also lies in the xy-plane, for example.

In particular, the nanomanipulator comprises a sample stage device with a mount, a sample stage arranged movably on the mount, and a further positioning unit for moving the sample stage relative to the mount. In addition, in particular the further positioning unit is controlled in order to rotate the sample stage with the sample relative to the mount based on the ascertained access angle in such a way that the fixed angle of the measuring tip corresponds to the access angle.

The sample stage is mounted on a mount rotatably about the z-direction, in particular.

In embodiments, the nanomanipulator comprises a cantilever, which at its first end is mounted at a fixed angle on the positioning unit and at the second end of which the measuring tip is arranged. In addition, the sample is arranged on a rotatable sample stage. Furthermore, the method comprises:
receiving an image of at least one part of the sample, wherein the image captures structures of the sample and a particle,
ascertaining, based on the received image, a linear removal trajectory for the particle in order to remove the particle in such a way that the removal trajectory intersects the particle, a length of the removal trajectory is longer than a size of the particle, and the removal trajectory is free of structures of the sample, and
controlling the sample stage in order to rotate the sample stage based on the ascertained removal trajectory in such a way that the fixed angle of the measuring tip is arranged perpendicular to the removal trajectory.

As a result, the particle can be removed along a trajectory arranged parallel to a direction in which lateral forces can be captured.

The removal trajectory is ascertained, for example, in such a way that on one side of the particle the removal trajectory projects beyond the particle by double the size of the particle. Additionally or instead, the removal trajectory is ascertained, for example, in such a way that on the other side of the particle the removal trajectory projects beyond the particle by one and a half times a diameter of the measuring tip.

The removal trajectory is, for example, a trajectory in the xy-plane.

In embodiments, the method comprises:
receiving images of at least one part of the sample which capture the measuring tip,
controlling a display device to represent the received images,
receiving a user input from a user in order to change an imaging scale of the represented images, and
controlling the positioning unit of the nanomanipulator in order to automatically change a speed of the measuring tip as a function of the imaging scale.

If the measuring tip is operated at constant speed and a user zooms into the recorded image (e.g., scanning electron image) (i.e., magnifies the imaging scale), then the movement of the measuring tip perceived by the user in the recorded image may be too high to allow expedient use of a mouse pointer, a joystick or an equivalent graphical user interface tool (GUI tool). By virtue of the fact that, in accordance with this embodiment, the speed of the measuring tip is automatically set as a function of the imaging scale (i.e., the magnification of the represented image), this activity is obviated for the user.

In embodiments, the method comprises:
receiving a user input which identifies a beginning of a macro creation and defines a macro control parameter for the macro creation,
receiving a plurality of macro user inputs for controlling the positioning unit of the nanomanipulator in order to move the measuring tip,
receiving a user input which identifies an end of the macro creation, and
storing the macro control parameter and the macro user inputs assigned to the macro control parameter.

In one example of a macro creation, receiving a plurality of macro-user inputs comprises receiving a user input for laterally moving the measuring tip and receiving a user input for withdrawing the measuring tip perpendicular to the sample (displacing and lifting movement, “move and lift”). A move and lift macro for combined movement of the measuring tip laterally with respect to the sample and perpendicularly to the sample away from the sample can thus be created. By virtue of a user applying this move and lift macro, a procedure in which the measuring tip is brought closer to a particle on the sample, the particle is contacted by the measuring tip and the particle adhering to the measuring tip is lifted can be realized by use of a single user input.

In embodiments, the method comprises receiving a user input from a game controller as an example of a graphical user interface. A game controller comprises, e.g., many programmable buttons and joysticks. The game controller can also comprise adaptive triggers with haptic feedback by way of voice coil actuators, which can change the resistance for a user as required. By way of example, an optimum force between measuring tip and sample surface can be better set in this case.

The game controller can comprise, for example, a plurality of inputs, such as for example analogue sticks, analogue triggers, digital buttons, direction buttons and capacitive touch pads with a click mechanism (e.g., dual shock). These inputs can be used for the sample stage movement and the measuring tip movement (e.g., with adapted speed by way of pressure-sensitive joysticks or buttons), the control of a scanning electron microscope (e.g., magnification, focus, stigmator, scanning strategies) and the like. Furthermore, the game controller can also give feedback to the user. For example, the game controller can vibrate if the deflection signal (e.g., the deflection of the cantilever) reaches a limit value. Moreover, a built-in light bar or a series of LEDs can be used to indicate various pieces of information, such as for example deflection signal, lateral signal, measuring tip limits, measuring tip state (approached, folded up, retracted) and leaving of the permitted region.

The game controller can also comprise a gyroscope and/or an acceleration sensor. Data captured by these devices can be used to find out whether a user is exhibiting fatigue phenomena and needs a break.

The game controller can also comprise one or more microphone arrays and/or a headphone connection (e.g., 3.5 mm stereo headphone connection). These devices can give acoustic feedback, for example.

In embodiments, the nanomanipulator comprises a cantilever, which at its base end is movably secured to the positioning unit, wherein the measuring tip is arranged at a free end of the cantilever. Furthermore, the method comprises:
receiving at least one scanning electron microscope image which at least partly captures the measuring tip and/or the cantilever,
ascertaining one or more properties of the measuring tip and/or of the cantilever by image analysis of the at least one received image, and
ascertaining a type and/or status of the measuring tip based on the ascertained property/-ies of the measuring tip and/or of the cantilever.

Various kinds of measuring tips are usually used when processing samples with the nanomanipulator. Moreover, measuring tips may change as a result of use, e.g., may become worn or soiled. The differences among the different measuring tips are generally so small that they cannot be detected either with the naked eye or with an optical microscope.

By way of recording the at least one scanning electron microscope image (SEM image) of the measuring tip and/or of the cantilever, said image having a very high spatial resolution, and image processing of the SEM image, it is nevertheless possible to ascertain the type and/or status of the measuring tip. It is thus possible to ensure that the correct type of measuring tip is used for processing the sample and/or the measuring tip has a required status (e.g., low degree of wear). By way of example, it is possible to ensure that the correct type of measuring tip is used for specific planned processing of the sample and/or a measuring tip has a status required for specific planned processing of the sample.

The at least one received scanning electron microscope image can optionally also capture at least one part of the sample.

In embodiments, the one or more properties of the measuring tip and/or of the cantilever comprise(s) a geometric shape of the measuring tip, an outer contour of the measuring tip, a length of the measuring tip, a taper angle of the measuring tip and/or a marking of the measuring tip and/or of the cantilever.

In embodiments, the type of the measuring tip comprises a manufacturer type of the measuring tip.

In embodiments, the status of the measuring tip comprises a degree of wear of the measuring tip and/or a contamination of the measuring tip.

In embodiments, the cantilever comprises a marking, in particular an identification marker and/or a QR code, ascertaining the one or more properties of the measuring tip and/or of the cantilever comprises capturing the marking by image analysis of the received image, and ascertaining the type and/or the status of the measuring tip comprises decoding the marking.

The marking is very small, for example, such that it cannot be captured either with the naked eye or with an optical microscope. The marking, in particular the identification marker and/or the QR code, has for example a size of 10 μm or less, 5 μm or less, 1 μm or less, and/or 0.1 μm or less. The marking, in particular the identification marker and/or the QR code, has for example a marking structure having a structure size of 1 μm or less, 0.1 μm or less, 50 nm or less, 30 nm or less, 20 mm or less, 10 nm or less, and/or 1 nm or less. The marking is, for example, a QR code having a pixel size of 1 μm or less, 0.1 μm or less, 50 nm or less, 30 nm or less, 20 mm or less, 10 nm or less, and/or 1 nm or less.

The marking is arranged on the cantilever, for example, in such a way that it does not interact with the laser beam of the light pointer device of the nanomanipulator. The marking is arranged on the cantilever, for example, at a distance from an incidence location and/or incidence region of the laser beam of the light pointer device at which the laser beam is incident on the cantilever.

In embodiments, the type and/or status of the measuring tip are/is ascertained based on the property/-ies ascertained by image analysis and based on predetermined data which comprise properties assigned for a plurality of different measuring tips.

By way of example, the type and/or status of the measuring tip are/is ascertained based on a comparison of the property/-ies ascertained by image analysis with the predetermined data. The predetermined data comprise a database, for example. The predetermined data comprise, for example, data entries for a plurality of different measuring tips with assigned properties of the respective measuring tip. The assigned properties of the respective measuring tip comprise, for example, a type of measuring tip, use data of the measuring tip (e.g., unused/used, frequency and/or duration of the previous use, date of first use), status of the measuring tip (e.g., degree of wear, soiling, damage), x-ray data of the measuring tip (e.g., data of the measuring tip captured with the aid of energy-dispersive x-ray spectroscopy (EDX)) and/or atomic force microscope resonance properties of the measuring tip. A resonance curve in relation to the atomic force microscope resonance properties of the measuring tip has, for example, a resonant frequency (i.e., a frequency of high and/or maximum oscillation amplitude), a quality factor (e.g., width of the resonance curve), a maximum oscillation amplitude upon excitation with a constant excitation amplitude and/or occurrence of further peaks alongside the resonance peak.

In embodiments, ascertaining the type and/or status of the measuring tip based on the property/-ies ascertained by image analysis and based on the predetermined data involves ascertaining whether the predetermined data comprise a data entry for the measuring tip captured in the SEM image or for the measuring tip arranged on the cantilever captured in the SEM image (referred to hereinafter for short as: captured measuring tip). If it is ascertained that the predetermined data comprise a data entry for the captured measuring tip, then the type and/or status of the captured measuring tip are/is ascertained, for example, based on a comparison of the ascertained property/-ies of the captured measuring tip with the data entry for the corresponding measuring tip in the predetermined data.

If it is ascertained that the predetermined data do not comprise a data entry for the captured measuring tip, then for example a data entry is ascertained for a similar measuring tip in the predetermined data which has the most commonalities with the captured measuring tip, for example, in the group of measuring tips comprised by the predetermined data in the form of data entries. The type and/or status of the captured measuring tip are/is then ascertained, for example, based on a comparison of the ascertained property/-ies of the measuring tip with the data entry for the measuring tip ascertained as similar in the predetermined data.

In embodiments, the method comprises fully automatically setting process parameters of the nanomanipulator based on the ascertained type and/or status of the measuring tip.

Examples of process parameters which are fully automatically set based on the ascertained type and/or status of the measuring tip are a speed at which the measuring tip is moved, withdrawal of the measuring tip from the sample if it is moved into the vicinity of an edge, retrieving a position of a bottommost point of the measuring tip from a database, sharpening or exchange of the measuring tip in the case of a contaminated and/or blunt measuring tip, and selective monitoring of possible bending of the measuring tip depending on the pointedness or bluntness of a measuring tip.

By way of example, for sharp measuring tips (e.g., measuring tips having a small radius of curvature of the apex of the measuring tip and/or having a small opening angle), a force between the measuring tip and the sample must not be chosen to be as high as for blunt measuring tips (e.g., measuring tips having a large radius of curvature of the apex of the measuring tip and/or having a large opening angle). This is because a high force more easily breaks off a sharp measuring tip. Furthermore, a sharp tip may more easily damage the sample. In order to limit the force, an approaching movement of the measuring tip to the sample can be slowed down.

By way of example, in a case in which the measuring tip is in contact with the sample and the intention is to move up a step laterally, the force is kept constant by a distance control loop.

However, a force peak occurs directly at the step. A sharp measuring tip can be withdrawn here as a precaution if it moves in proximity to an edge.

By way of example, there are measuring tips whose bottommost point is not visible in the SEM image. This applies particularly to blunt measuring tips. If the position of the bottommost point of the measuring tip is stored in a database, this information can be used to move to a particle more accurately.

If a measuring tip is contaminated or blunt, for example, then it is not suitable for removing small particles. In this case, before the particle is picked up by the measuring tip, a further process step can be introduced, in which the measuring tip is sharpened or the measuring tip is exchanged for some other better suited measuring tip.

By way of example, very sharp and soft measuring tips may bend temporarily during particle manipulation. This can be observed by use of SEM images. This monitoring is obviated in the case of blunt measuring tips.

In embodiments, the method comprises fully automatically controlling the positioning unit in order to move the measuring tip based on the ascertained type and/or status of the measuring tip.

In embodiments, the nanomanipulator comprises a loading device comprising a plurality of measuring tips and/or cantilevers with measuring tips arranged thereon, and the method comprises:
receiving a user input in relation to a particle removal strategy,
receiving predetermined data in relation to measuring tips available in the loading device,
selecting a data entry for a measuring tip in the predetermined data based on the particle removal strategy, and
controlling the loading device for:
   automatically picking up a measuring tip and/or a cantilever with a measuring tip from the loading device, the measuring tip corresponding to the data entry for a measuring tip selected in the predetermined data, and
   securing the picked-up measuring tip to the cantilever and/or securing the picked-up cantilever with the measuring tip to the positioning unit.

The predetermined data are received, e.g., from a storage device of the nanomanipulator and/or the loading device.

In accordance with a further aspect, a computer program product is proposed, comprising instructions which, upon execution of the program by at least one computer, cause the latter to carry out the method described above.

A computer program product, such as e.g. a computer program means, can be provided or supplied, for example, as a storage medium, such as e.g. a memory card, a USB stick, a CD-ROM, a DVD, or else in the form of a downloadable file from a server in a network. For example, in a wireless communications network, this can be effected by transferring an appropriate file with the computer program product or the computer program means.

In accordance with a further aspect, an apparatus for processing a sample is proposed. The apparatus comprises:
a nanomanipulator comprising a measuring tip for processing the sample and a positioning unit for moving the measuring tip, and
a control apparatus configured to carry out the method described above.

The respective unit, for example, the control apparatus, can be implemented in terms of hardware technology and/or else software technology. In the case of an implementation in terms of hardware technology, the respective unit can be embodied as an apparatus or as part of an apparatus, for example, as a computer or as a microprocessor. In the case of an implementation in terms of software technology, the respective unit can be embodied as a computer program product, as a function, as a routine, as part of a program code or as an executable object. Furthermore, the corresponding unit can also be embodied as part of a superordinate control system of the nanomanipulator.

“A(n); one” in the present case should not necessarily be understood as restrictive to exactly one element. Rather, a plurality of elements, such as for example two, three or more, can also be provided. Nor should any other numeral used here be understood to the effect that there is a restriction to exactly the stated number of elements. Rather, unless indicated otherwise, numerical deviations upwards and downwards are possible.

The embodiments and features described for the method aspects apply, mutatis mutandis, to the proposed computer program aspects and the apparatus aspects, and vice versa. The described method, computer program and apparatus aspects may be provided in isolation or combined. E.g., two methods as described above may be combined to form a new method.

Further possible implementations of the invention also encompass not explicitly mentioned combinations of features or embodiments that are described above or hereinafter with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in greater detail hereinafter on the basis of preferred embodiments with reference to the accompanying figures.

### BRIEF DESCRIPTION OF DRAWINGS

FIG. 1 shows an apparatus for analyzing and/or processing a sample, in accordance with one embodiment;

FIG. 2 shows an image of a portion of a sample to be processed by the apparatus from FIG. 1, in accordance with one embodiment;

FIG. 3 shows a cross section from FIG. 2 along the line III-III;

FIG. 4 shows an enlarged portion of the apparatus from FIG. 1 together with a light pointer device, in accordance with one embodiment;

FIG. 5 illustrates one example of a two-dimensional parameter space of the apparatus and/or of the sample from FIG. 1, an ascertained permitted region being identified in the parameter space;

FIG. 6 shows a view similar to FIG. 5, an ascertained permitted region and a warning region being identified in the parameter space;

FIG. 7 shows a view similar to FIG. 6, the ascertained permitted region and the warning region continuously merging into one another;

FIG. 8 shows a sample to be processed by the apparatus from FIG. 1 in cross-section, charges having accumulated on a surface of the sample;

FIG. 9 illustrates a drift movement of a measuring tip of the apparatus from FIG. 1 relative to a sample to be processed, in accordance with one embodiment;

FIG. 10 illustrates edge recognition of structures of a sample to be processed by the apparatus from FIG. 1, in accordance with one embodiment;

FIG. 11 illustrates ascertainment of position data of structures of a sample to be processed by the apparatus from FIG. 1, in accordance with one embodiment;

FIG. 12 illustrates a time duration since a last user input for controlling the apparatus from FIG. 1;

FIG. 13 illustrates ascertainment of position data of a defect of a sample to be processed by the apparatus from FIG. 1, in accordance with one embodiment;

FIG. 14 shows an image, recorded by an image recording device, of a portion of the sample from FIG. 13, wherein the image recording device was centered on the position of the defect ascertained in FIG. 13;

FIG. 15 illustrates ascertainment of an expedient access path for a measuring tip of the apparatus from FIG. 1 in order to remove a defect of the sample;

FIG. 16 shows a flowchart of a computer-implemented method for processing a sample with the apparatus from FIG. 1, in accordance with one embodiment;

FIG. 17 shows a flowchart of another computer-implemented method for processing a sample with the apparatus from FIG. 1, in accordance with one embodiment;

FIG. 18 shows a first application scenario of the method for processing a sample in accordance with the method of FIG. 17; and

FIG. 19 shows a second application scenario of the method for processing a sample in accordance with the method of FIG. 17.

### DETAILED DESCRIPTION

Unless indicated otherwise, elements that are identical or functionally identical have been provided with the same reference signs in the figures. Furthermore, it should be noted that the illustrations in the figures are not necessarily true to scale.

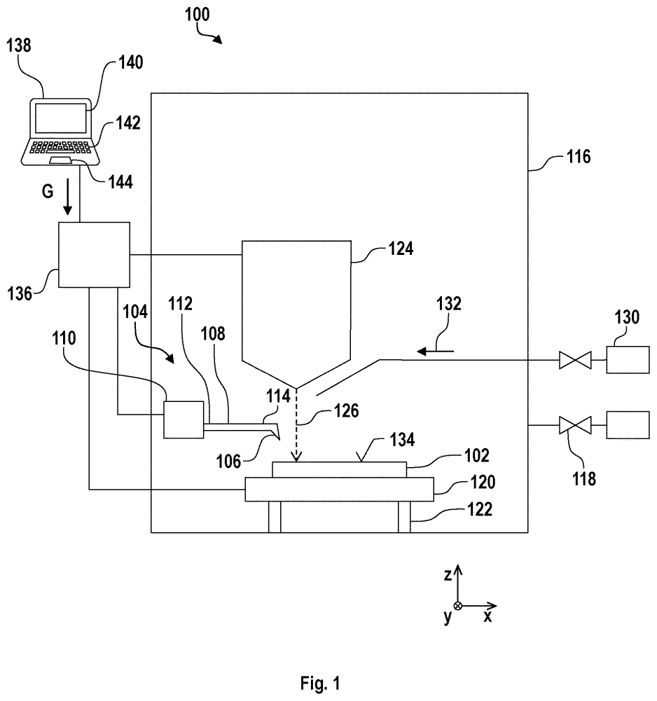

FIG. 1 schematically shows one exemplary embodiment of an apparatus 100 for analyzing and/or processing a sample 102 with the aid of an atomic force microscope 104 as one example of a nanomanipulator. The atomic force microscope 104 comprises a measuring tip 106 for analyzing and/or processing the sample 102. The measuring tip 106 is arranged on a cantilever 108 secured movably to a positioning unit 110 (movement unit). In particular, the cantilever 108 comprises a first end 112 (base end 112), at which the cantilever 108 is movably secured to the positioning unit 110. Furthermore, the cantilever 108 comprises a second end 114 (free end 114), at which the measuring tip 106 is arranged. With the aid of the positioning unit 110, the measuring tip 106 can be moved in three spatial directions x, y, z (translational movement in x-, y- and z-directions).

Although not shown in the figures, the positioning unit 110 can also comprise a stationary positioning component (which is secured, e.g., to a housing 116 of the apparatus 100) and a positioning component which is movable relative to the stationary positioning component and on which the base end 112 of the cantilever 108 is fixedly mounted. In this case, the base end 112 of the cantilever 108 together with the movable positioning component of the positioning unit 110 can be moved relative to the stationary positioning component of the positioning unit 110.

However, hereinafter an embodiment is described in which the base end 112 of the cantilever 108 is movably secured to the positioning unit 110.

The apparatus 100 comprises a housing 116, which is evacuable to a residual gas pressure of 1-10⁻¹⁰ mbar, e.g., 10⁻⁵-10⁻⁹ mbar, by use of a vacuum pump 118, for example. The atomic force microscope 104 is arranged in the housing 116. Furthermore, a sample stage 120 for holding the sample 102 is provided. The sample stage 120 is preferably held by the housing 116 by use of a mount 122. The sample stage 120 can furthermore comprise a further positioning unit (not illustrated), by means of which the sample stage 120 is displaceable in the three spatial directions x, y and z, for example, and is rotatable about at least one axis (e.g., the z-axis in FIG. 1), for example.

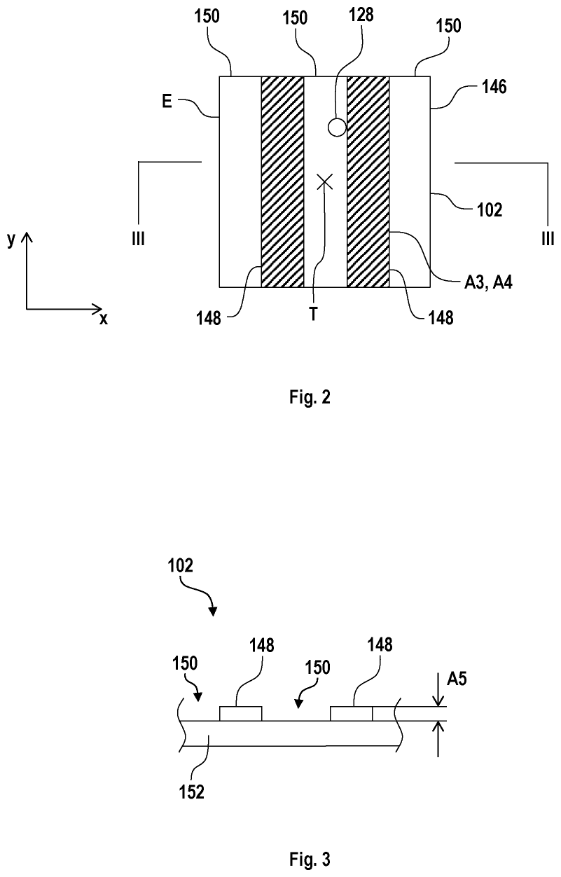

In addition, an electron column 124 is arranged in the housing 116. The electron column 124 is configured for providing an electron beam 126. The electron column 124 can in particular be embodied as an electron microscope and be used for monitoring picking up of a particle 128 (see FIG. 2) with the measuring tip 106.

In conjunction with a process gas providing unit 130, the electron column 124 can additionally be used for conducting particle beam-induced processing processes on the sample 102. For this purpose, for example, a process gas 132 is supplied by use of the process gas providing unit 130, and is irradiated by the particle beam 126.

A particle 128 (FIG. 2) adhering on a sample surface 134 of the sample 102 can be picked up with the measuring tip 106. For this purpose, the measuring tip 106 is correspondingly moved, for example, by use of the positioning unit 110. For assistance, the sample stage 120 can also be displaced by use of its further positioning unit (not shown). The picking up of the particle 128 by the measuring tip 106 is monitored live in particular with the electron microscope 124.

Afterwards, the measuring tip 106 is moved by use of the positioning unit 110 to a depository unit (not shown), where the particle 128 is transferred from the measuring tip 106 to the repository unit.

FIG. 1 additionally shows a control apparatus 136 for controlling the atomic force microscope 104, the sample stage 120, the electron microscope 124 and/or the process gas providing unit 130. A human-machine interface 138 can be provided as part of the control apparatus 136 or in a manner connected to the control apparatus 136 in wired or wireless fashion for data transfer. The human-machine interface 138 comprises, for example, a display device 140, a loudspeaker (not shown), a keyboard 142, a mouse pointer 144, a joystick, a game controller (not shown) or the like.

The illustrated apparatus 100 comprises a number of optional elements which do not necessarily have to be present. These are in particular the housing 116, the vacuum pump 118, the sample stage 120, the electron column 124, the process gas providing unit 130 and the human-machine interface 138.

FIG. 2 shows an image 146 (e.g., a scanning electron microscope image 146, for short: SEM image 146) of a portion of an exemplary sample 102. FIG. 3 shows the portion of the sample 102 shown as image 146 in FIG. 2 in a cross-sectional view along line III-III in FIG. 2. The sample 102 comprises, for example, structures 148 (e.g., absorber structures 148) with intervening trenches 150. Moreover, an exemplary particle 128 is shown on the sample 102, which particle lies in one of the trenches 150 at the edge of one of the absorber structures 148 and needs to be removed. The reference sign 152 in FIG. 3 denotes a substrate of the sample 102.

Removing particles 128 with the aid of the atomic force microscope 104 requires a manipulation of the measuring tip 106 with an accuracy of the order of magnitude of nanometres. It may be necessary to move to a particle 128 many times with the measuring tip 106 controlled by a user and to track the procedure in the SEM image 146 until finally adhering of the particle 128 to the measuring tip 106 is achieved and the particle 128 can be removed from the sample 102. This is a tiring activity in which small errors on the part of a user can easily lead to damage or destruction of the measuring tip 106 and/or of the sample 102.

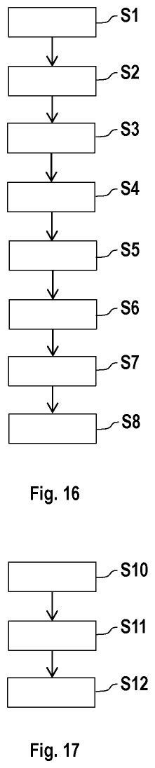

A computer-implemented method for processing a sample 102 with an atomic force microscope 104 is described below with reference to FIGS. 1 to 16.

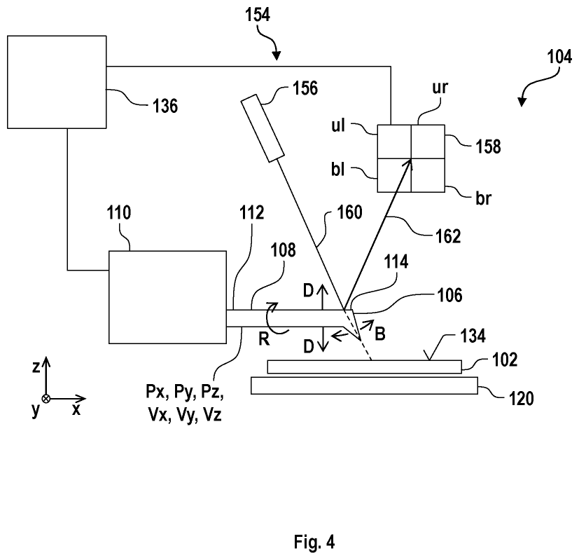

The method makes it possible to automatically and simultaneously monitor many parameters A1 to A6 (FIGS. 2, 3, 5) of the atomic force microscope 104 and/or of the sample 102 with the aid of the control apparatus 136 (FIG. 1). In particular, process parameters A1, A2 of the atomic force microscope 104 can be automatically monitored by the method. The process parameters A1, A2 of the atomic force microscope 104 are, for example, a position Px, Py, Pz (FIG. 4) of the base end 112 of the cantilever 108 in the three spatial directions x, y, z, said position being set by the positioning unit 110, and/or a deflection D of the cantilever 108 at its free end 114 in the z-direction.

Moreover, parameters A3 to A5 of the sample 102 can be automatically monitored by the method. The parameters A3 to A5 of the sample 102 are, for example, position data of structures 148 (FIGS. 2, 3) of the sample 102, such as for example x-, y- and z-coordinates of the structures 148.

FIG. 4 shows an enlarged view of the atomic force microscope 104 from FIG. 1.

The parameters A1 to A6 monitored in the method comprise, for example, two or more of the below-described parameters A1 to A6 of the atomic force microscope 104 and of the sample 102.

By way of example, a position Px, Py, Pz of the base end 112 of the cantilever 108 relative to the positioning unit 110 can be monitored by the method. Furthermore, a speed Vx, Vy, Vz of the base end 112 of the cantilever 108 relative to the positioning unit 110 can also be monitored. The position Px, Py, Pz and the speed Vx, Vy, Vz of the base end 112 of the cantilever 108 relative to the positioning unit 110 in the three spatial directions x, y, z are set in particular with the aid of the positioning unit 110. Current values of these parameters Px, Py, Pz, Vx, Vy and Vz are, for example, provided by the positioning unit 110 and/or captured with the aid of position sensors, speed sensors and/or acceleration sensors (not shown).

In addition, for example, a deflection D (FIG. 4) of the free end 114 of the cantilever 108 in the z-direction can be monitored by the method. The z-direction is arranged perpendicular to the sample 102, in particular perpendicular to a main extension plane E (xy-plane in FIG. 2) of the sample 102. The deflection D of the free end 114 of the cantilever 108 in the z-direction is caused by forces acting between the measuring tip 106 and the sample 102 and is proportional to a spring constant of the cantilever 108. A force acting on the cantilever 108 in the z-direction can thus be ascertained by capturing the deflection D.

Forces acting between the measuring tip 106 and the sample 102 can also cause a rotation R (torsion R, see FIG. 4) of the free end 114 of the cantilever 108 about the x-direction. This rotation R can also be monitored by the method proposed here.

The atomic force microscope 104 comprises, for example, a light pointer device 154 for capturing an extent of the deflection D of the free end 114 of the cantilever 108 in the z-direction, as illustrated in FIG. 4. The light pointer device 154 can also be used for capturing an extent of a rotation R of the free end 114 of the cantilever 108 about the x-direction.

The light pointer device 154 comprises, for example, a laser source 156 and a position-sensitive photodetector 158. A laser beam 160 emitted by the laser source 156 is directed at the free end 114 of the cantilever 108 and reflected from there onto the photodetector 158. The photodetector 158 comprises, for example, four photosensitive regions ul, ur, bl and br. In an undeflected position of the cantilever 108, the laser beam 160, 162 is reflected into the center of the photodetector 156, as shown in FIG. 4. However, if the cantilever 108 is deflected in a positive or negative z-direction (deflection D), then the reflected laser beam 162 shifts on the photodetector 158 as in the case of a light pointer. By measuring the received intensities in the four regions ul, ur, bl and br of the photodetector 158, it is possible to determine vertical and horizontal deflection signals (bending signals) of the cantilever 108. The deflection signals are proportional to forces acting on the cantilever 108 in the z-direction (normal force) and also to lateral forces acting in the x-direction or y-direction.

Furthermore, for example, a bending B (FIG. 4) of the measuring tip 106 relative to the cantilever 108 can also be monitored by the method. In particular, interaction of the measuring tip 106 with the sample 102 can result in a bending B (i.e., an elastic deformation) of the measuring tip 106 relative to the cantilever 108. By way of example, the measuring tip 106 may bend on account of a lateral movement of the measuring tip 106 (in the x- and/or y-direction in FIG. 4) while the measuring tip 106 is simultaneously in contact with the sample 102. An extent of this bending B of the measuring tip 106 can be ascertained by use of image processing in recorded images 146 (e.g., SEM images 146) of the measuring tip 106.

Furthermore, for example, parameters A3 to A6 of the sample 102 can also be automatically monitored by the method. The parameters A3 to A6 of the sample 102 comprise, for example, position data A3 to A5 of structures 148 (FIGS. 2, 3) of the sample 102. The position data A3 to A5 are, for example, x- and y-coordinates of the structures 148 (FIG. 2) and/or a height A5 of the structures 148 in the z-direction (FIG. 3). Moreover, a quantity of charge Q (A6) at the surface 134 of the sample 102 can be monitored (FIG. 8).

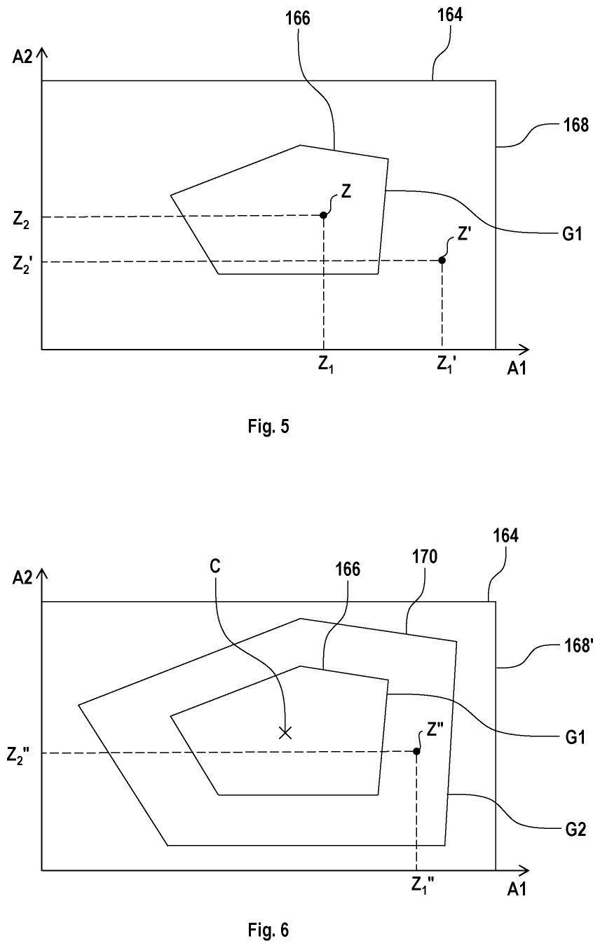

Monitoring two or more of the abovementioned parameters A1 to A6 of the atomic force microscope 104 and/or of the sample 102 enables a multidimensional parameter space 164 (FIG. 5) to be efficiently monitored.

A first step S1 of the method involves providing permitted value ranges for two or more parameters A1 to A6 of the atomic force microscope 104 and/or of the sample 102. The two or more parameters A1 to A6 span a multidimensional parameter space 164.

FIG. 5 illustrates by way of example the monitoring of two parameters A1, A2 (e.g., the Px and Py positions of the base end 112 of the cantilever). The two parameters A1, A2 span a two-dimensional parameter space 164.

Although not shown in the figures, more than two parameters A1 to A6 are preferably monitored. By way of example, it is possible to simultaneously monitor the position and speed of the base end 112 of the cantilever 108 in all three spatial directions x, y, z (corresponding to six parameters), the deflection D and rotation R of the free end 114 of the cantilever 108 (corresponding to two further parameters), the bending B of the measuring tip 106 (corresponding to one further parameter), the position A3, A4, A5 of the structures 148 of the sample 102 in three spatial directions x, y, z (corresponding to three further parameters) and the quantity of charge Q at the sample surface 134 (corresponding to one further parameter). In this example, a thirteen-dimensional parameter space can be monitored by the method.

The permitted value ranges provided are, for example, predetermined permitted value ranges which are stored in a storage device (not shown) of the control apparatus 136 and/or are received by the control apparatus 136. The permitted value ranges for the two or more parameters A1 to A6 are in each case one-dimensional value ranges, in particular.

A second step S2 of the method involves ascertaining a permitted region 166 in the multidimensional parameter space 164 based on the provided permitted value ranges for the two or more parameters A1 to A6. By way of example, the permitted region 166 can also be ascertained based on the permitted value ranges for the two or more parameters with the aid of a calculation of a probability of the sample 102 being damaged.

The permitted region 166 is ascertained by the control apparatus 136, for example, in step S2. Moreover, the permitted region 166 is ascertained, for example, fully automatically, i.e., without action by a user, in step S2.

In FIG. 5, the ascertained permitted region 166 has a polygonal shape. In other examples, an ascertained permitted region 166 can also have a different shape. Furthermore, a dimension of the permitted region 166 is, for example, exactly equal to a dimension of the monitored parameter space 164 (two-dimensional in the example in FIG. 5).

The reference sign 168 in FIG. 5 denotes a forbidden region in the monitored parameter space 164.

An optional third step S3 of the method involves ascertaining a warning region 170 (FIG. 6) in the parameter space 164. The warning region 170 is arranged in particular between the permitted region 166 and the forbidden region 168′.

In a fourth step S4 of the method, current values Z₁, Z₂ (FIG. 5) of the two or more monitored parameters A1 to A6 are received and/or future values Z′₁, Z′₂ of the two or more parameters A1 to A6 are ascertained.

The current values Z₁, Z₂ of the two or more monitored parameters A1 to A6 are obtained, for example, from the positioning unit 110, the light pointer device 154 or based on image processing of images 146 from the scanning electron microscope 124.

The future values Z′₁, Z′₂ of the two or more parameters A1 to A6 are predicted, for example, based on a received user input G. A user input G is effected, for example, with the aid of the human-machine interface 138 (FIG. 1). In this case, for example, a target position T (FIG. 2) of the measuring tip 106 input by a user by use of the human-machine interface 138 can be checked in regard to the monitored parameters A1 to A6.

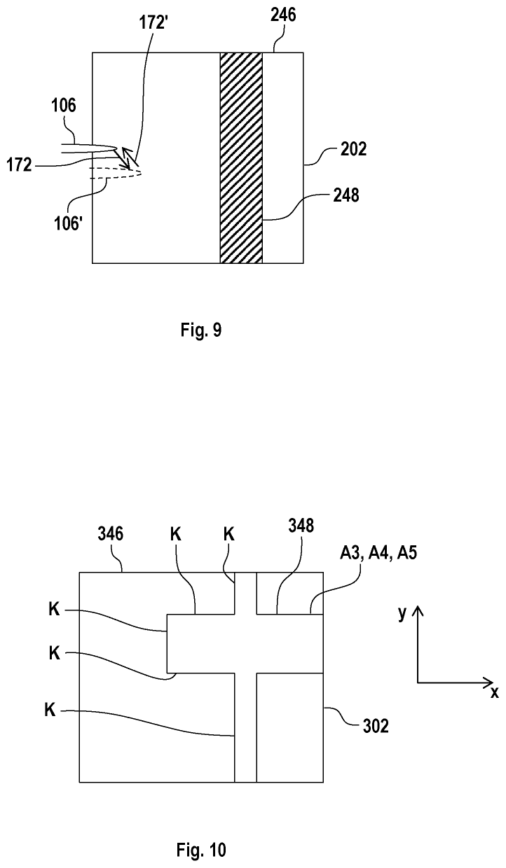

The future values Z′₁, Z′₂ of the two or more parameters A1 to A6 can, for example, additionally or instead also be predicted based on an ascertained drift movement 172 of the measuring tip 106 relative to the sample 202, as illustrated in FIG. 9. FIG. 9 shows an image 246 of a portion of a sample 202, which captures the measuring tip 106 and a structure 248 of the sample 202. In FIG. 9, a position of the measuring tip 106′ after a drift movement 172 of the measuring tip 106, 106′ has occurred (e.g., on account of thermal drift) is illustrated by dashed lines.

A fifth step S5 of the method involves ascertaining, based on the current values Z₁, Z₂ and/or the future values Z′₁, Z′₂, a corresponding current state point Z and/or future state point Z′ in the multidimensional parameter space 164 (FIG. 5). In addition, step S5 involves ascertaining whether the current and/or future state point Z, Z′ lies outside the permitted region 166.

The state point Z, Z′ is ascertained by the control apparatus 136, for example, in step S5. Moreover, the state point Z, Z′ is ascertained fully automatically, in particular, in S5.

In the example shown in FIG. 5, the ascertained current state point Z lies within the permitted region 166. Furthermore, the ascertained future state point Z′ lies outside the permitted region 166, in particular within the forbidden region 168.

If the optional step S3 was carried out, in which a warning region 170 (FIG. 6) is also ascertained in addition to the permitted region 166, then the following optional steps S6 and S7 are also carried out.

An optional sixth step S6 of the method involves ascertaining whether the current and/or future state point Z, Z′, Z″ lies within the ascertained warning region 170.

In an optional seventh step S7 of the method, the positioning unit 110 (FIG. 1) is controlled so that a movement of the measuring tip 106 is slowed down if it is ascertained in step S6 that the current and/or future state point Z, Z′, Z″ lies within the ascertained warning region 170.

In addition or instead, in step S7, the human-machine interface 138 can also be controlled in order to output a warning for a user if it is ascertained in step S6 that the current and/or future state point Z, Z′, Z″ lies within the ascertained warning region 170.

In an eighth step S8 of the method, the positioning unit 110 is automatically controlled in order to stop a movement of the measuring tip 106 (e.g., stopping a lateral movement of the measuring tip 106, i.e., stopping a movement of the base end 112 of the cantilever 108 in the x- and y-directions in FIG. 4) and/or in order to withdraw the measuring tip 106 in relation to the sample 102 (i.e., moving the base end 112 of the cantilever 108 in the positive z-direction in FIG. 4) if it is ascertained that the current and/or future state point Z, Z′, Z″ lies outside the permitted region 166, e.g., within the warning region 170 and/or the forbidden region 168, 168″. The controlling in step S8 is effected, for example, fully automatically by the control apparatus 138.

Stopping a movement of the measuring tip 106 and/or withdrawing the measuring tip 106 in relation to the sample 102 makes it possible for penetration into the forbidden region 168, 168′ to be prevented fully automatically, i.e., without the intervention of a user. Damage to the measuring tip 106 and/or the sample 102 can thus be prevented.

The ascertained permitted region 166, the ascertained warning region 170 and/or the ascertained forbidden region 168, 168′ of the monitored multidimensional parameter space 164 can have discrete limits G1, G2, as shown in FIGS. 5 and 6.

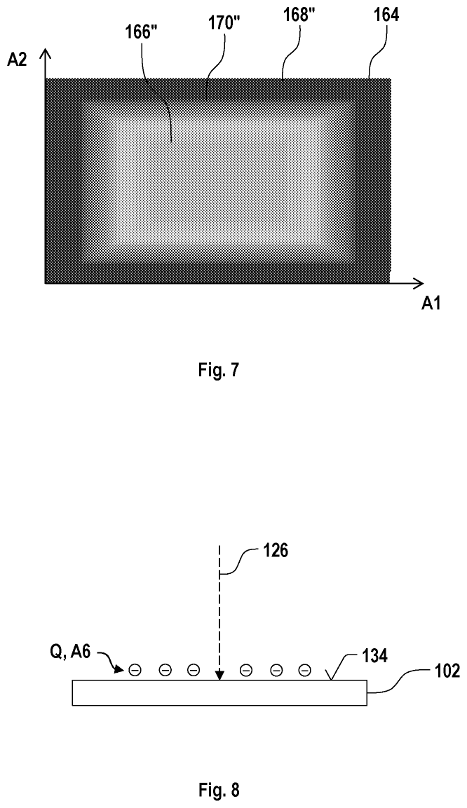

Alternatively, the ascertained permitted region 166″, the ascertained warning region 170″ and/or the ascertained forbidden region 168″ can also continuously merge into one another, as shown in FIG. 7. By way of example, the permitted region 166″, the warning region 170″ and/or the forbidden region 168″ can be ascertained based on a calculation of a probability of the sample 102 incurring damage (damage probability). By way of example, depending on a damage probability (e.g., a damage probability that is greater than a predetermined threshold value), a warning can be output and/or the positioning unit 110 can be controlled in order to stop a movement of the measuring tip 106 and/or in order to withdraw the measuring tip 106 in relation to the sample 102. By way of example, the positioning unit 110 can be controlled depending on the damage probability in such a way that a speed at which the measuring tip 106 is withdrawn from the sample 102 is all the greater, the greater the damage probability.

In the method, provision can optionally be made for recording one or more images 146 (FIG. 2) of at least one part of the sample 102 by use of an image recording device, such as for example the scanning electron microscope 124 (FIG. 1).

The electron beam 126 used in the process and a high electron beam dose applied can result in an accumulation of charge Q on the sample surface 134, as shown in FIG. 8.

In the proposed method, therefore, provision can optionally be made for one of the monitored parameters A1 to A6 of the atomic force microscope 104 and/or of the sample 102 to be a quantity of charge Q at the surface 134 of the sample 102. If it is ascertained in step S5 that a current and/or future value of the quantity of charge Q at the sample surface 134 lies outside a permitted value range, then the scanning electron microscope 124 can optionally be controlled to stop a recording of images 146 of the sample 102, and/or the human-machine interface 138 can be controlled to output a request for a user to perform a discharging process of the sample surface 134.

Moreover, in the method in step S1 provision can optionally be made for providing the permitted value ranges or a portion of the permitted value ranges for the two or more monitored parameters A1 to A6 by providing and/or ascertaining position data A3 to A5 of structures 148 of the sample 102 (FIGS. 2, 3).

By way of example, the position data A3 to A5 of the structures 148 of the sample 102 can be ascertained by use of image analysis of the one or more received images 146 of at least one part of the sample 102.

FIG. 10 shows one example in which position data A3 to A5 of structures 348 of a sample 302 are ascertained by use of analysis of an image 346 (e.g., SEM image 346) of at least one part of the sample 302. In FIG. 10, edge recognition of edges K of the structures 348 in the image 346 is performed during the image analysis. Edges K of structures 348 of a sample 302 often appear as the brightest elements in SEM images 346, such that their position in the x- and y-directions on the sample 302 can be ascertained well in an SEM image 346.

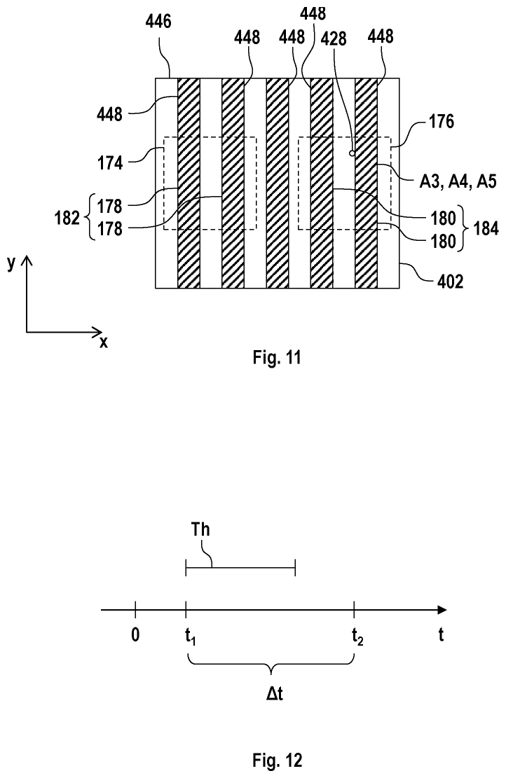

FIG. 11 illustrates a further example in which position data A3 to A5 of structures 448 of a sample 402 are ascertained by use of analysis of an image 446 (e.g., SEM image 446) of at least one part of the sample 402. In the example in FIG. 11, a defect 428 (e.g., a particle 428) is situated on the sample 402. The presence of one or a plurality of such defects 428 (e.g., particles 428) in the region of structures 448 of the sample 402 can make it more difficult to recognize and localize the structures 448. Therefore, in the example in FIG. 11, provision is made for the control apparatus 136 (FIG. 1) to receive an image 446 of at least one part of the sample 402, which image captures a defect-free region 174 and a defective region 176. In particular, a first portion 178 of the structures 448 is captured in the defect-free region 174. Furthermore at least one defect 428 (e.g., particle 428) and a second portion 180 of the structures 448 are captured in the defective region 176. Moreover, a geometric shape 182 of the first portion 178 of the structures 448 corresponds to a geometric shape 184 of the second portion 180 of the structures 448.

The defect-free region 174 allows better and more accurate determination of the structures 448. Therefore, firstly the geometric shape 182 of the first portion 178 of the structures 448 in the defect-free region 174 of the image 446 is ascertained by use of image analysis. Afterwards, the geometric shape 182 of the structures 178 ascertained for the defect-free region 174 of the sample 402 can be applied to the defective region 176 of the sample 402. In particular, position data A3, A4 (e.g., the x- and y-positions) of the second portion 180 of the structures 448 in the defective region 176 of the sample 402 can then be ascertained based on the ascertained geometric shape 182 of the first portion 178 of the structures 448 in the defect-free region 174 of the image 446.

Optionally, in the proposed method, provision can also be made for automatically moving to a target position T (FIG. 2) in an image 146 (e.g., SEM image 146). In particular, automatically moving to the target position T is effected on the basis of a target position T input by a user via a graphical user interface 144. The graphical user interface 144 can be, e.g., a mouse pointer 144 (FIG. 1) or else a joystick, game controller (not shown) or the like. For this purpose, the control apparatus 136 receives an image 146 (FIG. 2) of at least one part of the sample 102 and controls a display device 140 (FIG. 1) in order to represent the received image 146. A user viewing the image 146 on the display device 140 can identify (e.g., click on) a target position T for the measuring tip 106 by use of the graphical user interface 144. The control apparatus 136 then receives the target position T of the measuring tip 106 in the image 146, said target position having been input by the user by use of the graphical user interface 144. Subsequently, the positioning unit 110 of the atomic force microscope 104 is fully automatically controlled by the control apparatus 136 in such a way that the measuring tip 106 is moved to the target position T.

Optionally, in the proposed method, a deadman function can also be provided, which involves monitoring a time duration Δt since reception of a last user input G, as illustrated in FIG. 12. FIG. 12 shows a time t in the form of a timeline. In the example in FIG. 12, the last user input G took place at the point in time t₁. By way of example, at the point in time t₂ the control apparatus 136 checks the time duration Δt since reception of the last user input G. If the control apparatus 136 ascertains that the time duration Δt is greater than a predetermined threshold value Th (a predetermined time duration Th), then the deadman function becomes active. In particular, the control apparatus 136 then fully automatically controls the positioning unit 110 of the atomic force microscope 104 to bring the measuring tip 106 into the ascertained permitted region 166, 166″ (FIGS. 5 to 7) of the multidimensional parameter space 164 and/or into a predetermined safety state C (FIG. 6).

Optionally, in the proposed method, a fully automatic drift correction can also be provided, as illustrated in FIG. 9. For this purpose, the control apparatus 136 receives a plurality of images 246 of at least one part of the sample 202. The images 246 capture a structure 248 and/or marking of the sample 202 and the measuring tip 106. By way of example, the position of the measuring tip 106 relative to the structure/marking 248 may change over time as a result of a thermal drift. In FIG. 9, a position of the measuring tip 106′ after a drift movement 172 of the measuring tip 106, 106′ has occurred is illustrated by dashed lines. The control apparatus 136 ascertains the drift movement 172 of the measuring tip 106 relative to the structure/marking 248 by use of image analysis of the received images 246. Based on the ascertained drift movement 172, the control apparatus 136 then ascertains a drift correction 172′ and fully automatically controls the positioning unit 110 in order to move the measuring tip 106, 106′ according to the ascertained drift correction 172′.

Optionally, a fully automatic drift correction can also be effected—in addition or instead of based on the described image analysis—with the aid of predetermined model data. By way of example, a thermal drift can be approximated by a linear model.

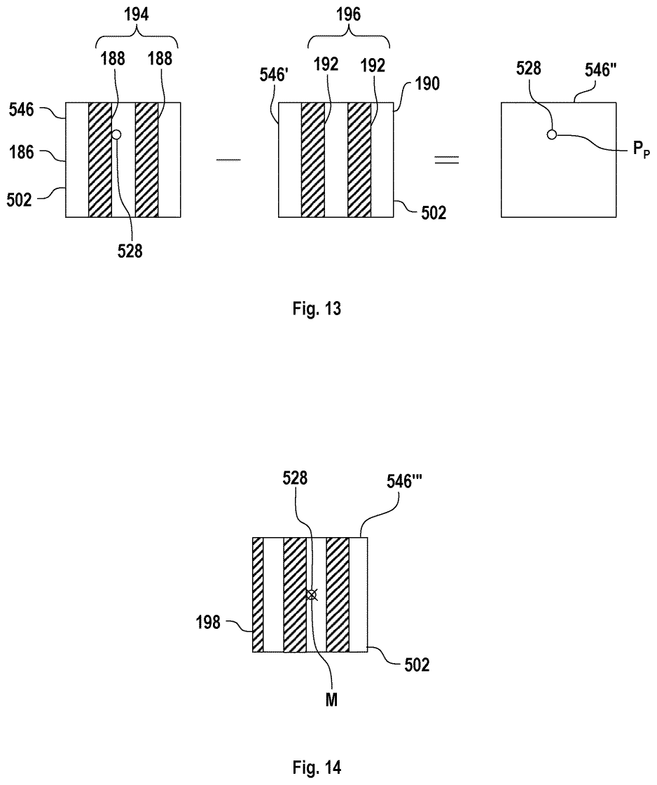

Optionally, in the proposed method, fully automatic particle recognition and image centering can also be provided, as illustrated in FIGS. 13 and 14. For this purpose, the control apparatus 136 controls an image recording device 124 (e.g., the scanning electron microscope 124, FIG. 1) in order to record a first image 546 of a defective portion 186 of a sample 502. The first image 546 captures first structures 188 of the sample 502 and one or more defects 528. Moreover, the control apparatus 136 controls the image recording device 124 in order to record a second image 546′ of a defect-free portion 190 of the sample 502. The second image 546′ captures second structures 192 of the sample 502, the geometric shape 196 of which corresponds to a geometric shape 194 of the first structures 188 in the first image 546.

One example in which the geometric shape 194 of first structures 188 of a sample 502 corresponds to the geometric shape 196 of second structures 192 of the sample 502 is that the first and second structures 188, 192 are part of a repeating pattern formed by structures 188, 192 of the sample 502. A further example in which the geometric shape 194 of first structures 188 of a sample 502 corresponds to the geometric shape 196 of second structures 192 of the same sample 502 is that a plurality of semiconductor chips of the same type are produced by use of one and the same sample 502 (e.g., a lithography mask 502). By way of example, in this case, the first structures 188 in the first image 546 serve for producing a first semiconductor chip (die) and the second structures 192 in the second image 546′ serve for producing a second semiconductor chip of the same type.

In the next step, the control apparatus 136 ascertains a difference image 546″ by subtracting the second image 546′ from the first image 546. Since the first and second structures 188, 192 correspond to one another (i.e., have the same geometric shape 194, 196), they are eliminated in the course of ascertaining the difference image 546″, such that no structures 188, 192 can be seen in the difference image 546″. Moreover, the defect 528 is imaged with greater contrast in the difference image 546″. Consequently, a position P_{P} of the defect 528 can be ascertained more accurately based on the difference image 546″. Therefore, position data P_{P} of the one or more defects 528 captured in the first image 546 are ascertained based on an image analysis of the difference image 546″.

The image recording device 124 is then controlled in order to record a third image 546″′ of a defective portion 198 of the sample 502 in such a way that the defect 528 is arranged at a predetermined position (e.g., in the image center M) in the third image 546″′.

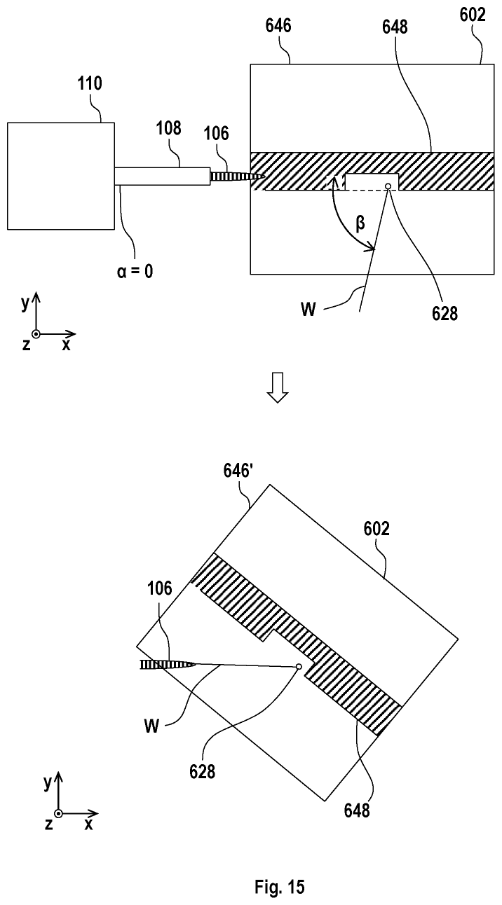

Optionally, in the proposed method, provision can also be made for fully automatically ascertaining an access angle β for a specific particle 628, as illustrated in FIG. 15. The background is that the cantilever 108 is arranged at a fixed angle α relative to the positioning unit 110 (the angle α is equal to zero in the example in FIG. 15). Consequently, an orientation of the measuring tip 106 relative to the cantilever 108 and the positioning unit 110 is fixed. It is then possible, as shown at the top in FIG. 15, for a particle 628, from the standpoint of the measuring tip 106, to be arranged in the shade of structures 648 of the sample 602 in such a way that direct access for the measuring tip 106 is blocked by the structures 648.

The control apparatus 136 can then control an image recording device 124 (e.g., the scanning electron microscope 124) in order to record an image 646 of at least one part of the sample 602, which image captures the structures 648 of the sample 602 and the particle 628. Next, the control apparatus 136 can ascertain a possible access angle β for the measuring tip 106 for processing the particle 628 in such a way that an access path W with the access angle β is free of structures 648 of the sample 602. The control apparatus 136 can thereupon control a positioning unit (not shown) of the sample stage 120 (FIG. 1) in order to rotate the sample stage 120 about the z-axis. In particular, the positioning unit (not shown) of the sample stage 120 is controlled based on the ascertained access angle β in such a way that the fixed angle α of the measuring tip 106 corresponds to the access angle β. Thus, as shown at the bottom in FIG. 15, the measuring tip 106 can access the particle 628 without obstructions.

Consequently, first the method described above makes it possible to fully automatically monitor a high-dimensional parameter space 164 in relation to process parameters A1 to A6 of the atomic force microscope 104 and/or properties of the sample 102. As a result, damage to the atomic force microscope 104 (e.g., the measuring tip 106) and the sample 102 can be prevented. Furthermore, in addition, as described above, optionally diverse fully automatic controls by the control apparatus 136 of the apparatus 110 are possible which allow a sample 102 to be processed more safely and more easily on nanometer scales with the atomic force microscope 104.

Optionally or alternatively, the proposed methods or systems provide an improved focusing approach for an image recording device (e.g., the scanning electron microscope 124) attached to or part of a nanomanipulator (e.g., the atomic force microscope 104), as illustrated in FIGS. 17 to 19.

FIG. 17 shows a flowchart of another computer-implemented method for processing a sample (e.g., sample 102) with the apparatus (e.g., apparatus 100) from FIG. 1, in accordance with one embodiment. The method may be employed for focusing the image recording device (e.g., the scanning electron microscope 124) on a feature of interest during both manual or automatic processing of a sample. The method may comprise the steps S10 to S12 as shown in FIG. 17 performed by a control unit (e.g., the control apparatus 136).

In a step S10, an image provided by an image recording device 724 is focused on a tip 706 (e.g., the measuring tip 106) and/or a sample 702 (e.g., a lithography mask). Focusing may be performed manually, i.e., under control of a human operator, or automatically, i.e., using an autofocus routine of the control unit, for example, based on a gradient detection algorithm performed on the image received from the image recording device 724, or a combination thereof. Optionally, the image provided by the image recording device 724 is focused on the measuring tip 706 and the sample 702 at the same time, e.g., while the tip 706 is in contact with the sample 702, i.e., when both the tip 706 and the sample 702 are located essentially at the same focal plane, i.e., within the focal depth of the image recording device 724.

In a step S11, an element shown within the focused image is selected as a target feature. For example, either the sample 702 or the tip 706 is selected as a target feature. Alternatively or in addition, a defect of the sample 702, e.g., a particle 728 located on a surface 734 of the sample 702 facing the image recording device 724, may be selected as feature of interest. Note that the selection may be direct or indirect. I.e., the user may select to follow the sample 702 when he or she aims to follow a particle 728 attached to the surface 734, or may select the tip 706 when he or she aims to follow a particle 728 attached to the tip 706. The selection may be performed manually by a user. For example, the user may select either the sample 702 or the tip 706 as a target feature using a corresponding physical or virtual selection switch of a user interface of the nanomanipulator 104 and/or the image recording device 724 (e.g., the human-machine interface 138). Alternatively, the selection may be performed (semi-)automatically or programmatically. For example, the selection may be made under the control of an automatic image analysis and/or object detection algorithm performed by the control apparatus 136.

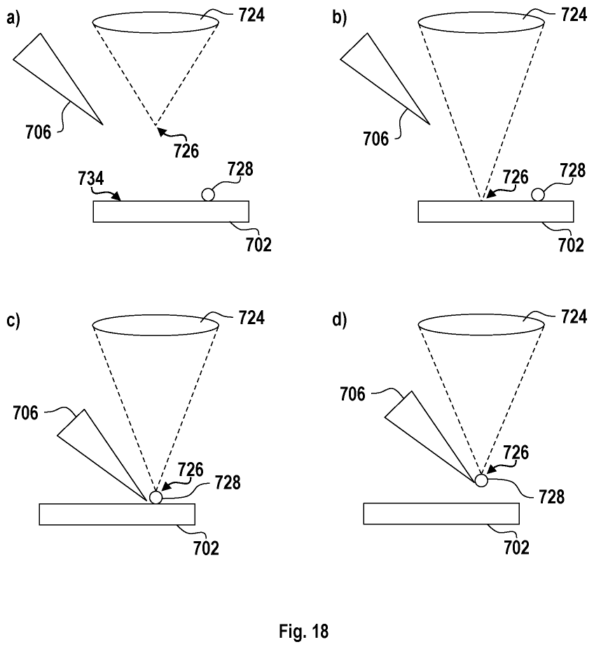

The selection step may be performed according to the preferences of a user or the needs of a specific task to be performed. For example, in a process for particle removal, based, for example, on the proposed process for fully automatic particle recognition described above, the selection may be performed as detailed below with respect to the first application scenario with respect to FIG. 18. As another example, in a process for replacing a probe (e.g., the tip 706), the selection may be performed as detailed below with respect to the second application scenario with respect to FIG. 18. As yet another example, in a process for navigating the sample 102 (e.g., a lithograph mask), the selection may be performed as detailed below.

In a step S12, a focal point 726 of the image recording device 724 is automatically set based on at least one operating parameter of one of the sample stage 120 and the positioning unit 110 of the nanomanipulator 104. The at least one operating parameter may be indicative of a vertical movement of the sample stage 120 or the positioning unit 110, respectively. For example, an operating parameter indicative of an absolute position in the z-direction of the sample stage 120 and/or the positioning unit 110 may be used. Alternatively, an initial position in the z-direction may be combined with an operating parameter indicative of a relative position or movement (i.e., change of the position) in the z-direction. For example, a motor speed or pulse sequence used to control a stepper motor or piezo actor may be used to keep track of a movement of the sample stage 120 and/or the positioning unit 110 in the z-direction. By keeping track of the position of the sample stage 120 and/or the tip 706 attached to the positioning unit 110 in the z-direction, the image recording device 724 can stay focused on the target feature selected in step S11 during processing, without the need for manual refocusing or employing a conventional autofocus routine.

As an example, if the sample 702 is selected as feature of interest and the sample stage is moved in the negative z-direction by 100 μm, i.e., further away from the measurement tip 106, the focal point 726 of the image recording device 724 is adjusted by the same amount, e.g., the focal point 726 is set to a plane 100 μm further away from the image recording device 724 than before. As another example, if the tip 704 is selected as feature of interest and the tip is moved in the positive z-direction by 50 μm, i.e., further away from the surface 734 of the sample 702, the focal point 726 of the image recording device 724 is adjusted by the same amount, e.g., the focal point 726 is set to a plane 50 μm closer to the image recording device 724.

FIG. 18 shows a first application scenario of the method for processing a sample 702 in accordance with the method of FIG. 17. In particular, FIG. 18 shows a process for autofocus adjustment during particle removal.

In a first phase shown in FIG. 18 a), a focal point 726 of the image recording device 724 is focused on the tip 706 of a nanomanipulator (e.g., the nanomanipulator 104). This may be performed manually or automatically as described above. This phase may be useful for characterizing the tip 706. For example, the operator may verify if the correct tip is attached to the position unit 110 of the nanomanipulator 104 and/or if the tip 704 is damaged.

In a second phase shown in FIG. 18 b), a focal point 726 of the image recording device 724 is focused on the sample 702. For example, a lithography mask may be used as a sample. As shown in FIG. 18 a) to c), one or more particles 728 may be located on a surface 734 of the sample 702. Focusing may be performed manually or automatically as described above. This phase may be useful for locating and/or characterizing the particle 728. For example, the operator may verify if the particle 728 is located in a critical area of the sample (e.g., the lithography mask) and can be removed with the tip 706 characterized in the first phase. Optionally, the sample 702 may be aligned in a horizontal direction, i.e., the x/y-plane, in a working area of the nanomanipulator 104, e.g., close to a center of the image provided by the image recording device 724.

In a third phase shown in FIG. 18 c), the tip 706 is lowered to the sample 702. If the focal point 726 of the image recording device 724 is set to follow the sample 702, the tip will slowly come into focus of the sample 702. Inversely, if the focal point 726 of the image recording device 724 is set to follow the tip 706, the sample 702 with the particle 728 will slowly come into focus as the tip 706 is lowered. Once the tip 706 is close to or in contact with the surface 734 of the sample 702, the focal depth of the image recording device 724 is usually sufficient to focus on the tip 706, the particle 728 and the sample 702 at the same time as shown in FIG. 18 c).

In a fourth phase shown in FIG. 18 d), the user selects the focal point 726 to follow the tip 704 of the nanomanipulator 104. Then, the operator moves the tip 706 to bring it in contact with the particle 728. The particle may then be moved horizontally and/or lifted off the surface 734 as shown. For example, the tip 706 may be lifted by 1 to 100 μm in an attempt to remove the particle 728 from the surface 734. Note that the particle 728 will stay in focus of the image recording device 724 during lift off if it is successfully attached to the tip 706, and will drift out of focus if the attachment is not successful, thereby providing the operator with visual feedback of the particle removal operation.

Note that the described focus following mechanism may be more reliable than conventional autofocus routines. For example, in a situation where both of a sample 702 and a tip 706 are currently in focus, e.g., in the situation depicted in FIG. 18 c), and one of the features is moved away from the focal plane, it may be difficult to decide for an autofocus routine whether to follow the sample 702 or the tip 706. Thus, by synchronizing the focal point adjustment to the movement of a feature of interest, e.g., the sample 702 or the tip 706, respectively, accidental locking of an autofocus routine to the wrong feature (i.e., a feature other than the feature of interest) can be avoided.

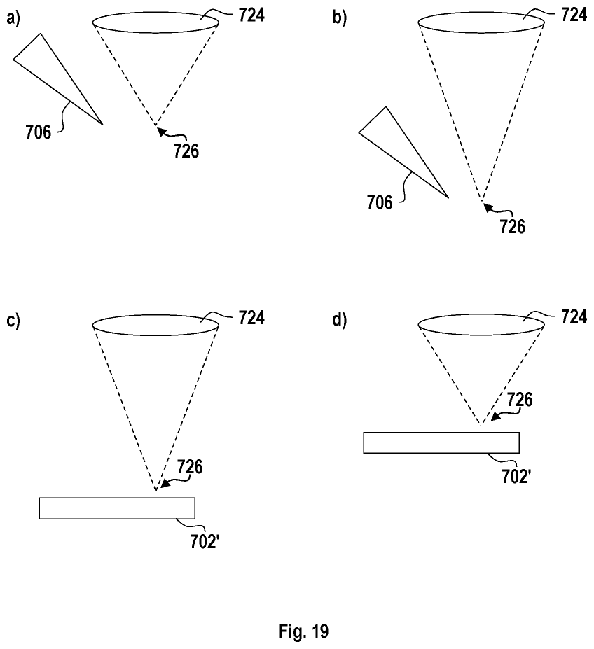

FIG. 19 shows a second application scenario of the method for processing a sample in accordance with the method of FIG. 17. In particular, FIG. 19 shows a process for autofocus adjustment during tip change.

In a first phase shown in FIG. 19 a) and b), a focal point 726 of the image recording device 724 is focused on a to be replaced tip 706 or a newly attached tip 706 of a nanomanipulator (e.g., the nanomanipulator 104). The tip 706 is selected as feature of interest. Thus, if a to be replaced tip 706 is lowered to a tip changing mask 702′ or a newly attached tip 706 is picked up from a tip changing mask 702′, the operator may inspect the respective tip 706. During this phase, the focus of the imaging recording device 724 stays focused on the tip 706 as shown in FIG. 19 a) and b).

In a second phase shown in FIG. 19 c) and d), a focal point 726 of the image recording device 724 is focused on the tip changing mask 702′. The tip changing mask 702′ is selected as feature of interest. During a tip change, the tip changing mask 702′ is typically moved away from the nanomanipulator 104, e.g., lowered by several millimetres. The tip changing mask 702′ is moved horizontally to select a new tip 706 and/or align the selected tip 706 with the attachment point of the nanomanipulator, e.g., the positioning unit 110. Then the tip changing mask 702′ with the new tip 706 is brought upwards again. Optionally, the horizontal allocation may be repeated (e.g., refined) once the tip changing mask 702′ is closer in the vertical z-direction to the attachment point. During this phase, the focus of the imaging recording device 724 stays focused on the tip changing mask 702′ as shown in FIG. 19 c) and d).

Further details of the process for changing the tip 706 using a tip changing mask 702′ are disclosed in international patent application WO 2016/193331A1, which is incorporated by reference herein in its entirety.

Attention is drawn to the fact that the automatic following of the focal point 726 of the image recording device 724 is also useful during larger movements and/or rotation of a sample 702 in the horizontal direction (not shown). For example, if the operator moves from one area of a lithographic mask to another area of the same mask related, for example, to a different circuit area or system component of a system on a chip (SoC). In such a procedure, the mask is typically lowered away from the nanomanipulator 104 to avoid accidental contacts with the tip 706. By selecting the sample (i.e., the mask) as feature of interest, the picture taken by the image recording device 724 (e.g., a SEM picture) remains in focus enabling the operator to identify the desired target region or feature easily.

In a further embodiment (not shown), the focal point 726 of the imaging device 724 may be alternated repeatedly, e.g., at a fixed interval of, for example, a few milliseconds, between the focal plane of the tip 706 and the focal plane of the sample 702. Accordingly two images may be generated and displayed alternatingly (e.g., in a stroboscopic manner), next to each other (e.g., in two different windows of the human-machine interface 138), or selectively based on the choice of an operator. In this way, the operator can monitor both the sample 702 and the tip 706 at essentially the same time, further improving control of the system 100.

Although the present invention has been described on the basis of exemplary embodiments, it is modifiable in diverse ways.

### LIST OF REFERENCE SIGNS

100 Apparatus
102 Sample
104 Nanomanipulator (atomic force microscope)
106, 106′ Measuring tip
108 Cantilever
110 Positioning unit
112 End
114 End
116 Housing
118 Pump
120 Sample stage
122 Mount
124 Electron column
126 Electron beam
128 Defect (particle)
130 Process gas providing unit
132 Process gas
134 Surface
136 Control apparatus
138 Human-machine interface
140 Display device
142 Keyboard
144 Mouse pointer
146 Image
148 Structure
150 Trench
152 Substrate
154 Light pointer device
156 Laser source
158 Photodetector
160 Laser beam
162 Laser beam
164 Parameter space
166, 166″ Region
168, 168′, 168″ Region
170, 170″ Region
172 Drift movement
172′ Drift correction
174 Region
176 Region
178 Portion
180 Portion
182 Shape
184 Shape
186 Portion
188 Structure
190 Portion
192 Structure
194 Shape
196 Shape
198 Portion
202 Sample
246 Image
248 Structure
302 Sample
346 Image
348 Structure
402 Sample
428 Defect (particle)
448 Structure
502 Sample
528 Defect (particle)
546, 546′, 546″, 546″ Image
602 Sample
628 Defect (particle)
646 Image
648 Structure
702 Sample
702′ Tip changing mask
706 Tip
724 Image recording device
726 Focal point
728 Particle
734 Surface
A1-A6 Parameters
α Angle
bl Region
br Region
B Bending
β Angle
C Safety state
D Deflection
At Time duration
E Plane
G User input
G1, G2 Limit
K Edge
M Center
Px, Py, Pz Position
P_{P} Position
Q Quantity of charge
R Rotation
S1-S8 Method steps
t Time
t₁, t₂ Time
T Target position
Th Threshold value
ul Region
ur Region
Vx, Vy, Vz Speed
W Path
X, y, Z Direction
Z, Z′, Z″ State point
Z₁, Z₁′, Z₁″ Value
Z₂, Z₂′, Z₂″ Value

1. A method, in particular a computer-implemented method, for processing a sample arranged on a sample stage with a nanomanipulator comprising a tip for processing the sample and a positioning unit for moving the tip, the method comprising the following steps:
focusing an image provided by an image recording device on the tip and/or the sample;
selecting the sample or the tip as a target feature; and
automatically setting a focal point of the nanomanipulator based on at least one operating parameter of one of the sample stage and the positioning unit indicative of a vertical movement of the sample stage and/or the positioning unit, respectively, so as to keep the target feature focused within the image provided by the image recording device during processing.

2. The method according to claim 1, wherein the image provided by the image recording device is focused on the tip and the sample while the tip is in contact with the sample.

3. The method according to claim 1, wherein the target feature is selected by an operator of the nanomanipulator through a human-machine interface.

4. The method according to claim 1, wherein
in case the sample is selected as target feature, the focal point is automatically set based on a z-value indicative of a vertical position of the sample stage; and
in case the tip is selected as target feature, the focal point is automatically set based on a z-value indicative of a vertical position of the positing unit.

5. The method according to claim 1, further comprising:
switching the target feature from the sample to the tip or vice versa, while the tip is not in contact with the sample.

6. The method according to claim 5, further comprising:
after switching the target feature, setting a focal point of the nanomanipulator based on the at least one operating parameter of the respective other one of the sample stage and the positioning unit.

7. The method according to claim 5, wherein the target feature is switched by an operator of the nanomanipulator through a human-machine interface.

8. The method according to claim 5, wherein the target feature is switched repeatedly between the sample and the tip, the method further comprising displaying a first image and a second image in a concurrent or alternating and/or stroboscopic manner, wherein
the first image is provided by the image recording device when the focal point is set based on the at least one operating parameter of one of the sample stage, such that the sample is in focus within the first image, and
the second image is provided by the image recording device when the focal point is set based on the at least one operating parameter of one of the positioning unit, such that the tip is in focus within the second image.

9. A method of using the method according to claim 1 for tracking a particle to be removed from the sample, comprising:
focusing the image provided by the image recording device when the tip of the nanomanipulator is in contact with a particle located on a surface of the sample;
selecting the tip as a target feature; and
separating the tip from the sample by operating the sample stage and/or the positioning unit in a vertical direction, while keeping the tip focused within the image provided by the image recording device during processing, so as to visually verify whether the particle is lifted by the tip from the surface of the sample.

10. The method according to claim 9, further comprising:
focusing the image provided by the image recording device on the tip to determine an initial horizontal position of the tip before the tip is in contact with the sample;
focusing the image provided by the image recording device on the sample to provide an initial horizontal position of the sample before the tip is in contact with the sample; and
bringing the tip in contact with the particle by operating the sample stage and/or the positioning unit in a vertical direction and/or aligning the horizontal positions of the tip and the sample by operating the sample stage and/or the positioning unit in a horizontal direction.

11. A method of using the method according to claim 1 for following a replacement tip during a tip change procedure, comprising:
focusing the image provided by the image recording device on a tip changing mask, carrying one or more replacement tips;
selecting the tip changing mask as a target feature; and
vertically aligning a target tip located on the tip changing mask in a central area of the image, while the focal point of the nanomanipulator is set on the tip changing mask.

12. The method of claim 11, further comprising:
attaching the target tip to the positioning unit;
selecting the target tip as feature of interest; and
lifting the target tip attached to the positioning unit from the tip changing mask, while the focal point of the nanomanipulator is set on the target tip.

13. A computer-implemented method for processing a sample with a nanomanipulator comprising a measuring tip for processing the sample and a positioning unit for moving the measuring tip, the method comprising the following steps:
a) providing permitted value ranges for two or more parameters of the nanomanipulator and/or of the sample, wherein the two or more parameters span a multidimensional parameter space,
b) ascertaining a permitted region in the multidimensional parameter space based on the provided permitted value ranges for the two or more parameters,
c) receiving current values and/or ascertaining future values of the two or more parameters,
d) ascertaining whether a state point corresponding to the current and/or future values of the two or more parameters in the multidimensional parameter space lies outside the permitted region, and
e) controlling the positioning unit in order to stop a movement of the measuring tip and/or in order to withdraw the measuring tip in relation to the sample if it is ascertained that the state point lies outside the permitted region.

14. The method according to claim 13, wherein the future values of the two or more parameters are predicted based on a received user input and/or based on an ascertained drift movement of the measuring tip relative to the sample.

15. The method according to claim 13, comprising:
ascertaining a warning region in the multidimensional parameter space for the two or more parameters,
ascertaining whether the current and/or future state point in the multidimensional parameter space lies within the ascertained warning region, and
controlling the positioning unit so that a movement of the measuring tip is slowed down and/or controlling a human-machine interface in order to output a warning if it is ascertained that the current and/or future state point lies within the ascertained warning region.

16. The method according to claim 13, wherein the permitted region, the warning region and/or a forbidden region of the multidimensional parameter space have discrete limits or continuously merge into one another.

17. The method according to claim 13, wherein the nanomanipulator comprises a cantilever, which at its base end is movably secured to the positioning unit, the measuring tip is arranged at a free end of the cantilever, and the two or more parameters of the nanomanipulator and/or of the sample comprise:
a position of the base end of the cantilever relative to the positioning unit,
a speed of the base end of the cantilever relative to the positioning unit,
a deflection of the free end of the cantilever in a z-direction arranged perpendicular to the sample,
a rotation of the free end of the cantilever about an x-direction arranged perpendicular to the z-direction,
a bending of the measuring tip relative to the cantilever, and/or
position data of structures of the sample.

18. The method according to claim 13, furthermore comprising:
receiving images of at least one part of the sample which have been recorded by a scanning electron microscope,
wherein the two or more parameters of the nanomanipulator and/or of the sample comprise a quantity of charge at a surface of the sample.

19. The method according to claim 13, wherein providing the permitted value ranges for the two or more parameters comprises providing and/or ascertaining position data of structures of the sample.

20.-26. (canceled)

27. An apparatus for processing a sample, comprising:
a nanomanipulator comprising a measuring tip for processing the sample and a positioning unit for moving the measuring tip, and
a control apparatus configured to carry out the method according to claim 1.
